(19) United States
(12) Patent Application Publication
(10) Pub. No.: US 2024/0304532 A1
(43) Pub. Date: Sep. 12, 2024

(54) MODULE AND ELECTRONIC DEVICE

(71) Applicant: CANON KABUSHIKI KAISHA, Tokyo (JP)

(72) Inventors: NORITAKE TSUBOI, Kanagawa (JP); KUNIHIKO MINEGISHI, Kanagawa (JP)

(21) Appl. No.: 18/585,403

(22) Filed: Feb. 23, 2024

(30) Foreign Application Priority Data
Mar. 7, 2023 (JP) 2023-034354
Jan. 29, 2024 (JP) 2024-011234

(51) Int. Cl. H01L 23/498; H01L 25/10

(52) U.S. Cl. CPC H01L 23/49811; H01L 25/105

(57) ABSTRACT

A module includes a first wiring board, a second wiring board, an electronic component, and a connecting unit. The connecting unit includes a first wiring member, a second wiring member, and a conductive bonding member. A first space continuous from the first wiring board to a first virtual plane and a second space continuous from the second wiring board to the first virtual plane are continuous with each other. At least one of a first condition and a second condition is satisfied. The first condition is a condition that a third space on an opposite side to the first space with respect to the first wiring member is continuous with the first space. The second condition is a condition that a fourth space on an opposite side to the second space with respect to the second wiring member is continuous with the second space.

### BACKGROUND OF THE INVENTION

### Field of the Invention

The present disclosure relates to a module and an electronic device.

### Description of the Related Art

From the viewpoint of miniaturization of the electronic device, the demand for high-density arrangement in a module included in an electronic device has been rising. As one of structures that realize the high-density arrangement, a three-dimensional mounting structure formed by stacking a plurality of wiring boards into multiple layers is known. As the three-dimensional mounting structure, Japanese Patent Laid-Open No. 2022-82426 discloses a module. The module disclosed in Japanese Patent Laid-Open No. 2022-82426 includes two wiring boards opposing each other and a wiring member interconnecting the two wiring boards.

An electronic component disposed on either one of the two wiring boards generates heat in response to power supply thereto. The heat generated in the electronic component is radiated from the electronic component to a space therearound, or is conducted to the wiring board on which the electronic component is disposed and then radiated to the space therearound, but the heat radiated to the space between the two wiring boards from the electronic component or the wiring board on which the electronic component is disposed is likely to remain between the two wiring boards. In addition, if the distance between the two wiring boards is small, One of the two wiring boards is likely to be affected by the heat from the other. Therefore, there is a demand for improvement in the structure between the two wiring boards.

### SUMMARY OF THE INVENTION

According to a first aspect of the present disclosure, a module includes a first wiring board having a main surface, a second wiring board disposed at an interval from the first wiring board and configured to overlap with the first wiring board in a direction orthogonal to the main surface, an electronic component mounted on the first wiring board or the second wiring board, and a connecting unit configured to interconnect the first wiring board and the second wiring board. The connecting unit includes a first wiring member disposed on the first wiring board side with respect to a first virtual plane between the first wiring board and the second wiring board, a second wiring member disposed on the second wiring board side with respect to the first virtual plane, and a conductive bonding member configured to bond the first wiring member and the second wiring member to each other. A first space continuous from the first wiring board to the first virtual plane and a second space continuous from the second wiring board to the first virtual plane are continuous with each other at the first virtual plane between the first wiring board and the second wiring board. At least one of a first condition and a second condition is satisfied. The first condition is a condition that a third space on an opposite side to the first space with respect to the first wiring member is continuous with the first space in a second virtual plane parallel to the first virtual plane and including the first wiring member and the first space. The second condition is a condition that a fourth space on an opposite side to the second space with respect to the second wiring member is continuous with the second space in a third virtual plane parallel to the first virtual plane and including the second wiring member and the second space.

According to a second aspect of the present disclosure, a module includes a first wiring board having a main surface, a second wiring board disposed at an interval from the first wiring board and configured to overlap with the first wiring board in a direction orthogonal to the main surface, an electronic component disposed between the first wiring board and the second wiring board, and a connecting unit configured to interconnect the first wiring board and the second wiring board. The connecting unit includes a first wiring member configured to overlap with the first wiring board in the direction orthogonal to the main surface and not overlap with the electronic component in the direction orthogonal to the main surface, a second wiring member configured to overlap with the second wiring board and the first wiring member in the direction orthogonal to the main surface and not overlap with the electronic component in the direction orthogonal to the main surface, and a conductive bonding member configured to bond the first wiring member and the second wiring member to each other. At least one of the first wiring member and the second wiring member does not continuously surround a space between the first wiring board and the second wiring board.

According to a third aspect of the present disclosure, a module includes a first wiring board having a main surface, a second wiring board disposed at an interval from the first wiring board and configured to overlap with the first wiring board in a direction orthogonal to the main surface, an electronic component disposed between the first wiring board and the second wiring board, and a connecting unit configured to interconnect the first wiring board and the second wiring board. The connecting unit includes a first wiring member configured to overlap with the first wiring board in the direction orthogonal to the main surface and not overlap with the electronic component in the direction orthogonal to the main surface, a second wiring member configured to overlap with the second wiring board and the first wiring member in the direction orthogonal to the main surface and not overlap with the electronic component in the direction orthogonal to the main surface, and a conductive bonding member configured to bond the first wiring member and the second wiring member to each other. One of the first wiring member and the second wiring member has a region that does not overlap with another of the first wiring member and the second wiring member in the direction orthogonal to the main surface of the first wiring board, the region intersects with the direction, and a driven component is mounted on the region.

Further features of the present invention will become apparent from the following description of exemplary embodiments with reference to the attached drawings.

### BRIEF DESCRIPTION OF THE DRAWINGS

FIG. 1 is a perspective view of a module according to a first embodiment.

FIG. 2 is a section view of the module according to the first embodiment.

FIG. 3 is a section view of part of the module according to the first embodiment.

FIG. 4A is an explanatory diagram of the module according to the first embodiment.

FIG. 4B is an explanatory diagram of the module according to the first embodiment.

FIG. 4C is an explanatory diagram of the module according to the first embodiment.

FIG. 5A is a section view of a module according to a first modification example.

FIG. 5B is a section view of a module according to a second modification example.

FIG. 6A is a section view of part of a module according to a third modification example.

FIG. 6B is a perspective view of a wiring member of the third modification example.

FIG. 7 is a section view of a module according to a second embodiment.

FIG. 8 is a section view of part of the module according to the second embodiment.

FIG. 9 is a side view of the module according to the second embodiment.

FIG. 10 is a perspective view of a module according to a third embodiment.

FIG. 11 is a perspective view of a module according to a fourth embodiment.

FIG. 12A is an explanatory diagram of the module according to the fourth embodiment.

FIG. 12B is an explanatory diagram of the module according to the fourth embodiment.

FIG. 12C is an explanatory diagram of the module according to the fourth embodiment.

FIG. 13A is an explanatory diagram of a camera according to a fifth embodiment.

FIG. 13B is an explanatory diagram of a module of a fourth modification example.

FIG. 14A illustrates a module of Comparative Example 1.

FIG. 14B illustrates a module of Comparative Example 2.

### DESCRIPTION OF THE EMBODIMENTS

Exemplary embodiments of the present disclosure will be described in detail below with reference to drawings.

### First Embodiment

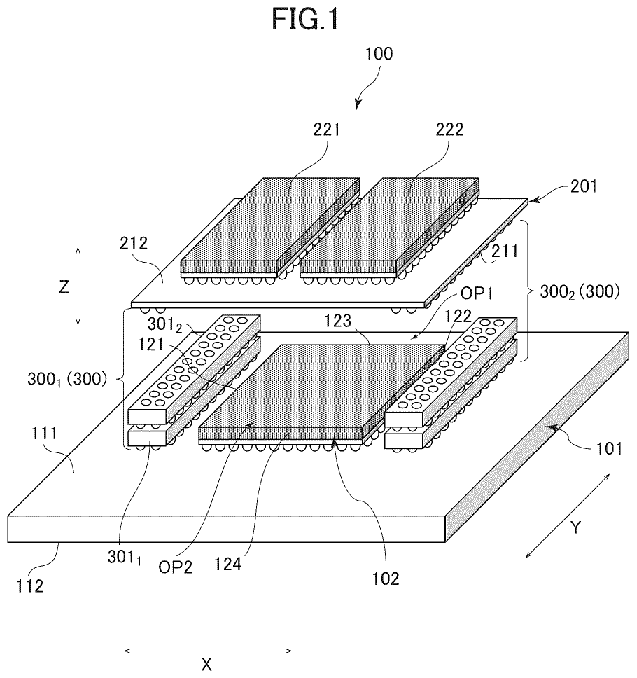

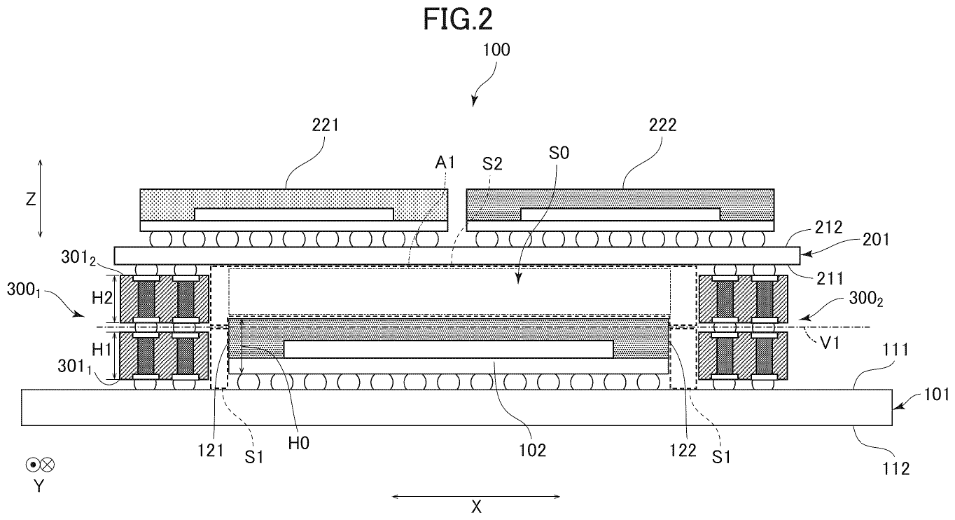

FIG. 1 is a perspective view of a module 100 according to a first embodiment. FIG. 2 is a section view of the module 100 according to the first embodiment. To be noted, in FIG. 1, the module 100 is illustrated in a partially exploded state in FIG. 1. The module 100 is incorporated in an electronic device such as a mobile device. That is, the module 100 is disposed inside a casing of the electronic device. Examples of the mobile device include smartphones, tablet computers, laptop computers, and portable gaming devices.

The module 100 is an example of an electronic module, and has a three-dimensional mounting structure. The module 100 includes a wiring board 101 serving as an example of a first wiring board, a wiring board 201 serving as an example of a second wiring board, and a plurality of connecting units 300. As a result of the wiring boards 101 and 201 being laminated via the plurality of connecting units 300, the size of the module 100 can be reduced. In the first embodiment, the plurality of connecting units 300 are two connecting units 300₁ and 300₂. The connecting unit 300₁ is an example of a first connecting unit. The connecting unit 300₂ is an example of a second connecting unit.

The wiring boards 101 and 201 are arranged at an interval in a Z direction serving as a lamination direction. The plurality of connecting units 300 are disposed between the wiring boards 101 and 201. That is, in the Z direction, the plurality of connecting units 300 are each disposed at a position overlapping with the wiring boards 101 and 201. The interval between the wiring boards 101 and 201 can be, for example, equal to or larger than 0.5 mm, or equal to or larger than 1.0 mm. In addition, the interval between the wiring boards 101 and 201 can be, for example, equal to or smaller than 10 mm, or equal to or smaller than 5 mm.

The plurality of connecting units 300 each electrically and mechanically interconnect the wiring boards 101 and 201. The plurality of connecting units 300 electrically interconnect, for example, a power supply line, a grounding line, and a signal line of the wiring board 101 and a power supply line, a grounding line, and a signal line of the wiring board 201.

In addition, the module 100 includes electronic components 102, 221, and 222. The electronic component 102 is disposed between the wiring boards 101 and 201. The electronic component 102 is an example of a first electronic component, and the electronic components 221 and 222 are each an example of a second electronic component. The electronic components 102, 211, and 222 are each a semiconductor device, that is, an integrated circuit component such as a semiconductor package. The electronic components 102, 211, and 222 are each an electronic component that is mounted on the surface such as a ball grid array (BGA) or a land grid array (LGA). In the first embodiment, the electronic component 102 is mounted on the wiring board 101, and the electronic components 221 and 222 are mounted on the wiring board 201.

The wiring boards 101 and 201 are each a printed wiring board. In addition, the wiring boards 101 and 201 are each a rigid wiring board. The wiring board 101 has two main surfaces 111 and 112. The wiring board 201 has two main surfaces 211 and 212.

In the Z direction, at least part of the wiring board 201 overlaps with the wiring board 101. That is, in the Z direction, at least part of the main surface 211 of the wiring board 201 faces the main surface 111 of the wiring board 101. In the first embodiment, the entirety of the wiring board 201 overlaps with the wiring board 101 in the Z direction.

Here, “A” facing “B” includes “A” directly facing “B” and “A” facing “B” with a different member therebetween, the different member including neither a member including “A” nor a member including “B”. In addition, “A” directly facing “B” includes “A” facing “B” with a space therebetween. In the example of FIGS. 1 and 2, in the Z direction, the main surface 211 of the wiring board 201 faces the main surface 111 of the wiring board 101 with the connecting units 300 and the electronic component 102 therebetween.

The main surface 112 of the wiring board 101 is a main surface on the opposite side to the main surface 111. The main surface 212 of the wiring board 201 is a main surface on the opposite side to the main surface 211. In the first embodiment, the main surface 111 is an example of a first main surface, the main surface 211 is an example of a second main surface, and the main surface 212 is an example of a third main surface.

The Z direction is a direction orthogonal to the main surface 111, that is, an out-of-plane direction of the main surface 111. In other words, the Z direction is a normal direction of the main surface 111. Directions orthogonal to the Z direction will be referred to as an X direction and a Y direction. The X direction and the Y direction are orthogonal to each other. The X direction and the Y direction are directions parallel to the main surface 111, that is, in-plane directions of the main surface 111.

To be noted, in the first embodiment, the main surfaces 112, 211, and 212 are substantially parallel to the main surface 111. In addition, the main surface 111 is a substantially flat surface. The main surface 111 may have small unevenness and distortion.

The electronic component 102 is disposed between the main surface 111 of the wiring board 101 and the main surface 211 of the wiring board 201. In the first embodiment, the electronic component 102 is mounted on the main surface 111 of the wiring board 101. The electronic components 221 and 222 are mounted on the main surface 212 of the wiring board 201.

The connecting units 300 are disposed between the main surface 111 of the wiring board 101 and the main surface 211 of the wiring board 201 such that the interval between the wiring boards 101 and 201 is such a value that the the electronic component 102 does not interfere (come into contact) with the wiring board 201. That is, the connecting units 300 electronically and mechanically interconnect the main surface 111 of the wiring board 101 and the main surface 211 of the wiring board 201, and also play a role as a spacer. The height of the connecting units 300 in the Z direction is larger than the height of the electronic component 102 in the Z direction.

The connecting units 300 are disposed at positions not overlapping with the electronic component 102 in the Z direction. In the first embodiment, the connecting units 300₁ and 300₂ are apart from the electronic component 102 in the X direction.

The electronic component 102 approximately has a quadrangular shape as viewed in the Z direction, and has four side surfaces 121, 122, 123, and 124. The side surface 122 is a side surface on the opposite side to the side surface 121, and the side surface 124 is a side surface on the opposite side to the side surface 123. In the first embodiment, the side surfaces 121 and 122 are parallel to each other, and the side surfaces 123 and 124 are parallel to each other. The side surfaces 121 and 122 are each a side surface intersecting with the side surfaces 123 and 124. The side surface 121 is an example of a first side surface, and the side surface 122 is an example of a second side surface. The side surface 123 is an example of a third side surface, and the side surface 124 is an example of a fourth side surface.

The connecting unit 300₁ is disposed to face the side surface 121 of the electronic component 102 in the X direction. The connecting unit 300₂ is disposed to face the side surface 122 of the electronic component 102 in the X direction. In the first embodiment, at least part of the connecting unit 300₁ faces the side surface 121 of the electronic component 102 in the X direction. In addition, at least part of the connecting unit 300₂ faces the side surface 122 of the electronic component 102 in the X direction.

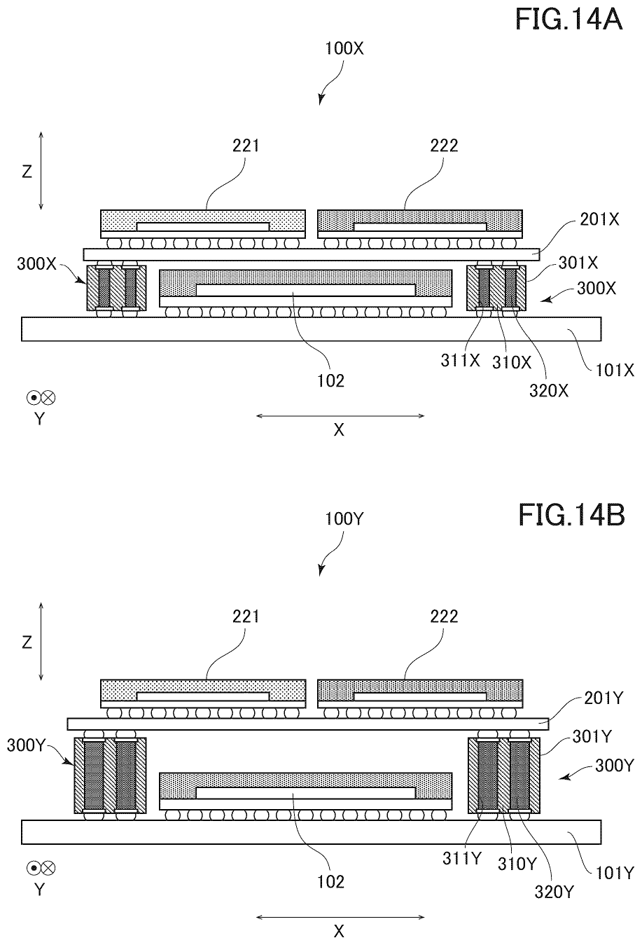

Comparative Examples 1 and 2 will be described below. FIG. 14A illustrates a module 100X of Comparative Example 1. FIG. 14B illustrates a module 100Y of Comparative Example 2. To be noted, in Comparative Examples 1 and 2, elements similar to those of the first embodiment will be denoted by the same reference signs.

The module 100X includes a wiring board 101X, a wiring board 201X, and electronic components 102, 221, and 222. The electronic component 102 is mounted on the wiring board 101X, and the electronic components 221 and 222 are mounted on the wiring board 201X. The module 100X includes a plurality of connecting units 300X. The configuration of the connecting units 300X is different from the configuration of the connecting units 300.

The module 100Y includes a wiring board 101Y, a wiring board 201Y, and electronic components 102, 221, and 222. The electronic component 102 is mounted on the wiring board 101Y, and the electronic components 221 and 222 are mounted on the wiring board 201Y. The module 100Y includes a plurality of connecting units 300Y. The configuration of the connecting units 300Y is different from the configurations of the connecting units 300 and 300X.

The connecting unit 300X of the module 100X of Comparative Example 1 includes a wiring member 301X. The wiring member 301X is a rigid wiring board. The wiring member 301X includes an insulating substrate 310X and conductive members 320X. The insulating substrate 310X has through holes 311X extending in the Z direction, and the conductive members 320X each include a solid or hollow columnar portion provided in corresponding one of the through holes 311X and a pair of pads disposed on the two sides of the columnar portion in the Z direction. That is, the wiring member 301X is a two-layer printed wiring board that is easy to manufacture. The insulating substrate 310X is formed from an insulating member, for example, FR-4. In the pair of pads of the conductive member 320X, one pad is bonded to a pad of the wiring board 101X via solder, and the other pad is bonded to a pad of the wiring board 201X via solder.

The electronic component 102 is a component that generates heat in response to power supply thereto. Accompanied by the improvement in the functionality and performance of the electronic component 102, there is an increasing tendency in the amount of power consumption of the electronic component 102, and there is an increasing tendency in the amount of heat generation in the electronic component 102. If the interval between the electronic component 102 and the wiring board 201X is small, the heat dissipation efficiency of the electronic component 102 is low, and therefore the processing speed of the electronic component 102 needs to be lowered such that the temperature of the electronic component 102 does not exceed a prescribed temperature.

Therefore, to improve the processing speed of the electronic component 102, that is, to improve the heat dissipation efficiency, increasing the interval between the electronic component 102 and the wiring board 201Y by, as in the module 100Y of Comparative Example 2, setting the height of the connecting unit 300Y in the Z direction to be larger than the height of the connecting unit 300X in the Z direction can be considered.

The connecting unit 300Y includes a wiring member 301Y longer than the wiring member 301X in the Z direction. The wiring member 301Y is a rigid wiring board. The wiring member 301Y includes an insulating substrate 310Y and conductive members 320Y. The insulating substrate 310Y has through holes 311Y extending in the Z direction, and the conductive members 320Y each include a solid or hollow columnar portion provided in corresponding one of the through holes 311Y and a pair of pads disposed on the two sides of the columnar portion in the Z direction. That is, the wiring member 301Y is a two-layer printed wiring board that is easy to manufacture. The insulating substrate 310Y is formed from an insulating member, for example, FR-4. In the pair of pads of the conductive member 320Y, one pad is bonded to a pad of the wiring board 101Y via solder, and the other pad is bonded to a pad of the wiring board 201Y via solder.

As described above, by setting the height of the wiring member 301Y in the Z direction to be larger than the height of the wiring member 301X in the Z direction, the interval between the wiring board 201Y and the electronic component 102 can be increased. However, by setting the height of the wiring member 301Y in the Z direction to be larger than the height of the wiring member 301X in the Z direction, the wiring member 301Y becomes large in the X direction and the Y direction, and as a result, the module 100Y becomes large and the electronic device including the module 100Y also becomes large.

Here, a manufacturing method for the wiring member 301X will be described. First, an insulating parent material is prepared, and the insulating substrate 310X is manufactured by boring the through holes 311X in the insulating parent material by using a drill. Next, the conductive members 320X are formed in the through holes 311X of the insulating substrate 310X by using metal plating, metal paste, or the like. The wiring member 301X is manufactured in this manner. Next, by bonding the wiring member 301X to the wiring boards 101X and 201X by soldering, the module 100X is manufactured. Since the wiring member 301X is a two-layer printed wiring board, the wiring member 301X can be manufactured in a simple process, and the wiring member 301X can be manufactured at a low cost.

A case of manufacturing a wiring member of Comparative Example 3 different from Comparative Examples 1 and 2 that is taller in the Z direction than the wiring member 301X will be described. An end surface of the wiring member of Comparative Example 3 in the Z direction is set to have the same area as an end surface of the wiring member 301X in the Z direction.

If it is attempted to bore a through hole having the same diameter as Comparative Example 1 in the insulating parent material to manufacture the wiring member of Comparative Example 3, since the insulating parent material is taller, the hole boring length of the drill is larger, and as a result, the drill is more likely to be broken or deformed, which shortens the lifetime of the drill. Therefore, increasing the diameter of the through hole 311Y as in Comparative Example 2 can be considered as a measure for this. In the case of boring a plurality of through holes 311Y in the insulating parent material, the distance between the plurality of through holes 311Y also needs to be increased. As a result, the area of an end surface of the wiring member 301Y in the Z direction becomes larger than the area of an end surface of the wiring member 301X in the Z direction. Since the area of the end surface of the wiring member 301Y is increased, the wiring boards 101Y and 201Y also increase in size, the module 100Y also increases in size, and the electronic device including the module 100Y also increases in size.

The connecting units 300 of the first embodiment have different configurations than the connecting units 300X and 300Y of Comparative Examples 1 and 2. To be noted, the configuration of the connecting unit 300₁ is the same as the configuration of the connecting unit 300₂, and the configuration of only one of the connecting units 300 will be described below.

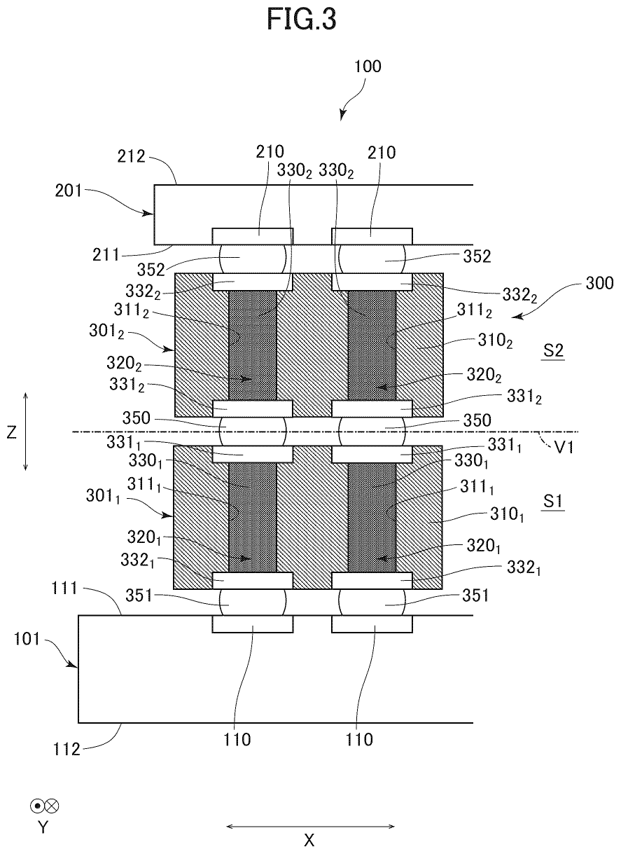

FIG. 3 is a section view of part of the module 100 according to the first embodiment. The connecting unit 300 includes a plurality of wiring members arranged in the Z direction. The plurality of wiring members are connected in the Z direction in a multi-tier arrangement. Each wiring member is a wiring board. Each wiring member is preferably a rigid wiring board. In addition, each wiring member is preferably a two-layer printed wiring board that is easy to manufacture.

The plurality of wiring members are the two wiring members 301₁ and 301₂ in the first embodiment. The wiring member 301₁ is an example of a first wiring member, and the wiring member 301₂ is an example of a second wiring member. In the Z direction, the wiring members 301₁ and 301₂ do not overlap with the electronic component 102. In the Z direction, at least part of the wiring member 301₁ overlaps with the wiring boards 101 and 201. In the first embodiment, the entirety of the wiring member 301₁ overlaps with the wiring boards 101 and 201. In addition, in the Z direction, at least part of the wiring member 301₂ overlaps with the wiring boards 101 and 201. In the first embodiment, the entirety of the wiring member 301₂ overlaps with the wiring boards 101 and 201. In the Z direction, at least part of the wiring member 301₁ overlaps with the wiring member 301₂. In the first embodiment, the entirety of the wiring member 301₁ overlaps with the wiring member 301₂. In addition, in the Z direction, at least part of the wiring member 301₂ overlaps with the wiring member 301₁. In the first embodiment, the entirety of the wiring member 301₂ overlaps with the wiring member 301₁.

In addition, the connecting unit 300 includes a plurality of bonding members 350 bonding the wiring member 301₁ and the wiring member 301₂ to each other, a plurality of bonding members 351 bonding the wiring member 301₁ to the wiring board 101, and a plurality of bonding members 352 bonding the wiring member 301₂ to the wiring board 201. The bonding members 350 to 352 are members serving as part of the wiring electrically and mechanically interconnecting the wiring boards 101 and 201. The bonding members 350 to 352 are each, for example, a conductive member including solder. The solder is preferably solder of Sn—Ag—Cu or solder of Sn—Bi. That is, the wiring member 301₁ and the wiring member 301₂ are soldered to each other, the wiring member 301₁ and the wiring board 101 are soldered to each other, and the wiring member 301₂ and the wiring board 201 are soldered to each other. That is, the bonding via the bonding members 350 to 352 is typically soldering. The distance between the wiring member 301₁ and the wiring member 301₂ can be equal to or smaller than 1.0 mm, or equal to or smaller than 0.5 mm. In addition, the distance between the wiring member 301₁ and the wiring member 301₂ can be equal to or larger than 0.01 mm, or equal to or larger than 0.05 mm. Similarly, the distance between the wiring member 301₁ and the wiring board 101 and the distance between the wiring member 301₂ and the wiring board 201 each can be equal to or smaller than 1.0 mm, or equal to or smaller than 0.5 mm. In addition, the distance between the wiring member 301₁ and the wiring board 101 and the distance between the wiring member 301₂ and the wiring board 201 each can be equal to or larger than 0.01 mm, or equal to or larger than 0.05 mm.

To be noted, although the bonding members 350, 351, and 352 preferably include solder, the configuration is not limited to this. For example, the bonding members 350, 351, and 352 may include an inorganic material such as copper, silver, gold, or aluminum, or may include an organic material such as conductive rubber. In addition, the bonding members 350, 351, and 352 each may be, for example, a cured product of an organic conductive adhesive. In addition, the bonding members 350, 351, and 352 each may be an anisotropic conductive film (ACF).

The wiring member 301₁ includes an insulating substrate 310₁ and a plurality of conductive members 320₁ provided on the insulating substrate 310₁. The insulating substrate 310₁ is a substrate having a rectangular parallelepiped shape having through holes 311₁ of the same number as the conductive members 320₁. The plurality of through holes 311₁ each extend from a first end to a second end of the insulating substrate 310₁ in the Z direction. The insulating substrate 310₁ is an example of a first insulating substrate. The insulating substrate 310₁ is constituted by an insulating member. For example, the insulating substrate 310₁ is preferably a member based on resin such as FR-4, but may be based on an inorganic material such as ceramics.

The through holes 311₁ are each an example of a first through hole. The through holes 311₁ each have a columnar shape extending from the first end to the second end of the insulating substrate 310₁ in the Z direction. The through holes 311₁ may be each bored by using, for example, a laser, but is preferably bored by using a drill similarly to Comparative Example 1 described above from the viewpoint of easy manufacture.

The conductive members 320₁ are respectively provided in the through holes 311₁. The conductive members 320₁ are each an example of a first conductive member. The conductive members 320₁ are each a metal member. The material of the metal member is not limited, but is preferably, for example, copper, silver, gold, aluminum, or the like. The manufacturing method of each conductive member 320₁ is not limited, and possible examples thereof include a method of plating the insulating substrate 310₁ with metal, and a method of supplying a metal paste to the insulating substrate 310₁ and curing the metal paste.

The wiring member 301₂ includes an insulating substrate 310₂ and a plurality of conductive members 320₂ provided on the insulating substrate 310₂. The insulating substrate 310₂ is a substrate having a rectangular parallelepiped shape having through holes 311₂ of the same number as the conductive members 320₂. The plurality of through holes 311₂ each extend from a first end to a second end of the insulating substrate 310₂ in the Z direction. The insulating substrate 310₂ is an example of a second insulating substrate. The insulating substrate 310₂ is constituted by an insulating member. For example, the insulating substrate 310₂ is preferably a member based on resin such as FR-4, but may be based on an inorganic material such as ceramics.

The through holes 311₂ are each an example of a second through hole. The through holes 311₂ each have a columnar shape extending from the first end to the second end of the insulating substrate 310₂ in the Z direction. The through holes 311₂ may be each bored by using, for example, a laser, but is preferably bored by using a drill similarly to Comparative Example 1 described above from the viewpoint of easy manufacture.

The conductive members 320₂ are respectively provided in the through holes 311₂. The conductive members 320₂ are each an example of a second conductive member. The conductive members 320₂ are each a metal member. The material of the metal member is not limited, but is preferably, for example, copper, silver, gold, aluminum, or the like. The manufacturing method of each conductive member 320₂ is not limited, and possible examples thereof include a method of plating the insulating substrate 310₂ with metal, and a method of supplying a metal paste to the insulating substrate 310₂ and curing the metal paste.

In the first embodiment, the configuration of the wiring member 301₂ is similar to the configuration of the wiring member 301₁. In the description below, description will be given focusing on one conductive member 320₁, one through hole 311₁, one conductive member 320₂, and one through hole 311₂ corresponding to each other.

At least part of the conductive member 320₁ is provided in the through hole 311₁. In the first embodiment, the conductive member 320₁ includes a solid or hollow columnar portion 330₁ provided in the through hole 311₁, a pad 331₁ provided at a first end of the columnar portion 330₁ in the Z direction, and a pad 332₁ provided at a second end of the columnar portion 330₁ in the Z direction.

In the case where the columnar portion 330₁ is a hollow columnar portion in which conductor is not provided inside, the inside of the conductive member 320₁ may be empty, or the inside of the columnar portion 330₁ may be filled with an insulator such as resin. In addition, the hollow or solid columnar portion 330₁ may include, for example, an outer conductor obtained by plating the insulating substrate 310₁ with copper, and an inner conductor such as solder disposed inside the outer conductor.

At least part of the conductive member 320₂ is provided in the through hole 311₂. In the first embodiment, the conductive member 320₂ includes a solid or hollow columnar portion 330₂ provided in the through hole 311₂, a pad 331₂ provided at a first end of the columnar portion 330₂ in the Z direction, and a pad 332₂ provided at a second end of the columnar portion 330₂ in the Z direction.

In the case where the columnar portion 330₂ is a hollow columnar portion in which conductor is not provided inside, the inside of the columnar portion 330₂ may be empty, or the inside of the conductive member 320₂ may be filled with insulator such as resin. In addition, the hollow or solid columnar portion 330₂ may include, for example, an outer conductor obtained by plating the insulating substrate 310₂ with copper, and an inner conductor such as solder disposed inside the outer conductor.

The pad 331₁ of the wiring member 301₁ and the pad 331₂ of the wiring member 301₂ are bonded to each other via a corresponding bonding member 350 among the plurality of bonding members 350.

Here, the wiring board 101 includes, on the main surface 111, a plurality of pads 110 of the same number as the plurality of pads 332₁ of the wiring member 301₁. The wiring board 201 includes, on the main surface 211, a plurality of pads 210 of the same number as the plurality of pads 332₂ of the wiring member 301₂.

The plurality of pads 110 of the wiring board 101 are each bonded to a corresponding pad 332₁ among the plurality of pads 332₁ of the wiring member 301₁ via a corresponding bonding member 351 among the plurality of bonding members 351.

The plurality of pads 210 of the wiring board 201 are each bonded to a corresponding pad 332₂ among the plurality of pads 332₂ of the wiring member 301₂ via a corresponding bonding member 352 among the plurality of bonding members 352.

As a result of the connecting unit 300 configured as described above, the pads 210 of the wiring board 201 are electrically connected to the pads 110 of the wiring board 101 via the bonding members 352, the conductive members 320₂ of the wiring member 301₂, the bonding members 350, the conductive members 320₁ of the wiring member 301₁, and the bonding members 351.

Here, as illustrated in FIGS. 2 and 3, a virtual plane V1 is defined. The virtual plane V1 is an example of a first virtual plane. The virtual plane V1 is typically defined between the wiring members 301₁ and the wiring members 301₂. The virtual plane V1 is, for example, a virtual plane parallel to the main surface 111. The virtual plane V1 is defined between, for example, the main surfaces 111 and 211, and is preferably defined at a position that is in an equal distance from the main surfaces 111 and 211. In addition, not the wiring members 301₂ but the wiring members 301₁ are typically positioned between the virtual plane V1 and the main surface 111, and not the wiring members 301₁ but the wiring members 301₂ are typically positioned between the virtual plane V1 and the main surface 211. In addition, the virtual plane V1 is typically defined such that the bonding members 350 are positioned in the virtual plane V1. In particular, the virtual plane V1 is typically defined such that the bonding members 350 of the connecting unit 300₁ and the bonding members 350 of the connecting unit 300₂ are positioned therein.

The wiring board 101 is disposed on one side with respect to the virtual plane V1, and the wiring board 201 is disposed on the other side that is opposite to the one side with respect to the virtual plane V1. In the Z direction, at least part of the wiring board 201 overlaps with the wiring board 101. In the first embodiment, the entirety of the wiring board 201 overlaps with the wiring board 101. The wiring members 301₁ are disposed on the wiring board 101 side with respect to the virtual plane V1 in the Z direction, that is, between the wiring board 101 and the virtual plane V1. The wiring members 301₂ are disposed on the wiring board 201 side with respect to the virtual plane V1 in the Z direction, that is, between the wiring board 201 and the virtual plane V1. The wiring members 301₁ and the wiring members 301₂ are electrically and mechanically connected to each other via the plurality of bonding members 350 arranged at intervals in the X direction and the Y direction.

An open space S0 is defined between the wiring boards 101 and 201 by the wiring boards 101 and 201. As viewed in the Z direction, when the outer shape of the wiring board 201 is defined as an outline, the space S0 is an inner space that is inside the outline as viewed in the Z direction and that is interposed between the plurality of connecting units 300.

The space S0 includes a space S1 and a space S2. The space S1 is an example of a first space, and the space S2 is an example of a second space. The space S1 is a space continuous from the main surface 111 of the wiring board 101 to the virtual plane V1. The space S2 is a space continuous from the main surface 211 of the wiring board 201 to the virtual plane V1.

In the space between the wiring boards 101 and 201, the spaces S1 and S2 are continuous with each other at the virtual plane V1. That is, the continuous spaces S1 and S2 constitute an open space. The spaces S1 and S2 may be any of vacuum spaces, pressure-reduced spaces, spaces in which a fluid is present, and spaces in which the same medium is present. Examples of the fluid include gas and/or liquid. In the case where a member including a mounted component mounted on the wiring board 101 or the wiring board 201 is present between the wiring boards 101 and 201, the spaces S1 and S2 are a space excluding members between the wiring boards 101 and 201. A flow path for a fluid such as air including the continuous spaces S1 and S2 may be formed between the wiring boards 101 and 201. As a result of the fluid in the flow path including the spaces S1 and S2 coming into contact with the electronic component 102 mounted on the wiring board 101, the heat dissipation of the electronic component 102 can be efficiently performed.

In the first embodiment, the insulating substrate 310₁ is manufactured by boring the through holes 311₁ in the insulating parent material by using a drill. Then, by forming the conductive members 320₁ in the through holes 311₁, the wiring member 301₁ is manufactured. The wiring member 301₂ is also manufactured by a manufacturing method similar to that of the wiring member 301₁. As described above, each of the wiring members 301₁ and 301₂ is a two-layer printed wiring board, and since these are manufactured through a simple process, the wiring members 301₁ and 301₂ can be manufactured at a low cost.

In addition, since the connecting unit 300 includes a plurality of wiring members, that is, the two wiring members 301₁ and 301₂ in the first embodiment, the interval between the wiring boards 101 and 201 in the Z direction can be adjusted by the two wiring members 301₁ and 301₂. Typically, the interval in the Z direction between the wiring boards 101 and 201, that is, the interval in the Z direction between the electronic component 102 and the wiring board 201 is increased. In other words, the volume of a space A1 between the electronic component 102 and the wiring board 201 is increased. As a result, the heat dissipation efficiency of the electronic component 102 is improved. Since the space A1 is expanded, temperature rise in the space A1 can be suppressed. As described above, the module 100 advantageous for improving the structure between the two wiring boards 101 and 201 can be provided.

In addition, although this increases the height of the connecting unit 300 in the Z direction, the height of each of the wiring members 301₁ and 301₂ in the Z direction can be set to be equal to or smaller than a half of the height of the connecting unit 300. Since the height of the insulating parent material in the Z direction can be set to be small when manufacturing the wiring member 301₁, the through holes 311₁ can be easily bored in the insulating parent material with a thin drill. In addition, the pitch between the plurality of through holes 311₁ does not need to be increased as in Comparative Example 2. Therefore, in the wiring member 301₁, the plurality of through holes 311₁ are arranged at a small pitch, and the bored through holes 311₁ are all thin, that is, the columnar portions 330₁ of the conductive members 320₁ are formed to be thin, and therefore the area of the end surface of the wiring member 301₁ in the Z direction is small, and thus the wiring member 301₁ is miniaturized. The wiring member 301₂ is also miniaturized similarly to the wiring member 301₁. Since the connecting unit 300 is miniaturized, the module 100 is miniaturized. Further, the electronic device incorporating the module 100 is also miniaturized.

In addition, since the wiring members 301₁ and 301₂ arranged at an interval in the Z direction are bonded to each other via the plurality of bonding members 350 arranged at intervals in the X direction or the Y direction, a flow of air is generated between the space S0 between the wiring boards 101 and 201 and a space outside the space S0 via the gaps between the plurality of bonding members 350, and thus the heat dissipation efficiency of the electronic component 102 is further improved.

The configuration of the wiring member 301₂ may be the same as the configuration of the wiring member 301₁, and the dimensions of the wiring member 301₂ may be the same as the dimensions of the wiring member 301₁. The wiring member 301₁ will be described below. In FIGS. 1 to 3, the lengthwise direction of the wiring member 301₁ is the Y direction, the width direction of the wiring member 301₁ is the X direction, and the height direction of the wiring member 301₁ is the Z direction. The height direction of the electronic component 102 is the Z direction. The dimension of the wiring member 301₁ in the Y direction serving as the lengthwise direction is larger than the dimension of the electronic component 102 in the Y direction.

That is, both sides of the electronic component 102 in the X direction respectively face the connecting units 300₁ and 300₂. That is, the side surface 121 of the electronic component 102 faces the connecting unit 300₁ in the X direction, and the side surface 122 of the electronic component 102 faces the connecting unit 300₂ in the X direction. Further, the gap between the plurality of bonding members 350, the gap between the plurality of bonding members 351, and the gap between the plurality of bonding members 352 can function as a flow path for a fluid such as air.

Further, at least one of the wiring members 301₁ and the wiring members 301₂, both in the first embodiment, do not continuously surround the space S0 (spaces S1 and S2). In the example of FIG. 1, neither of the wiring members 301₁ and the wiring members 301₂ continuously surround the space S0 (spaces S1 and S2). That is, the space S0 is interposed between the plurality of wiring members 301₁ apart from each other and between the plurality of wiring members 301₂ apart from each other. Further, on both sides of the electronic component 102 in the Y direction, the connecting unit is not disposed and the spaces S1 and S2 are wide open. In other words, the side surface 123 side of the electronic component 102 in the Y direction serves as an opening OP1 of the space S0, and the space S0 communicates with the outside space through the opening OP1. In addition, the side surface 124 side of the electronic component 102 in the Y direction serves as an opening OP2 of the space S0, and the space S0 communicates with the outside space through the opening OP2. Here, the outside space is a space on the opposite side to the space S0 with respect to the connecting units 300. According to the configuration described above, the flow of a fluid such as air is secured between the space S0 (that is, the spaces S1 and S2) and the outside space, and thus the heat dissipation efficiency of the electronic component 102 is further improved.

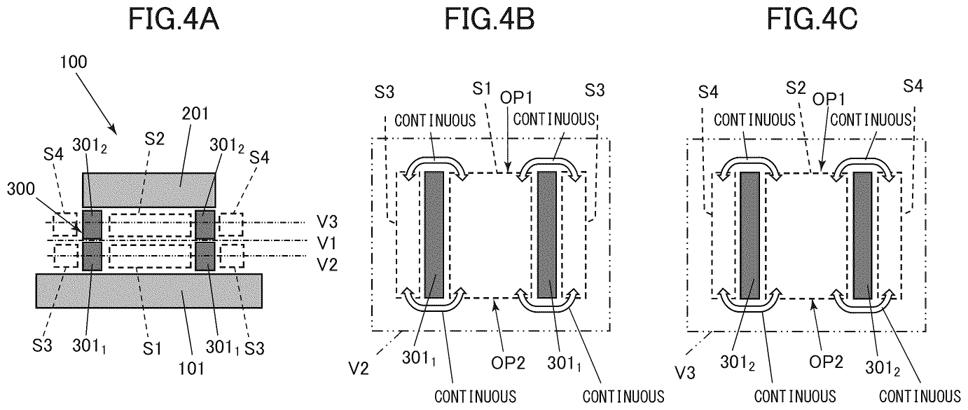

FIGS. 4A to 4C are explanatory diagrams of the module 100 of the first embodiment. FIG. 4A is a schematic section view of the module 100 in the X-Z plane. As illustrated in FIG. 4A, a virtual plane V2 parallel to the virtual plane V1 and including the wiring members 301₁ and the space S1 is defined. In addition, a virtual plane V3 parallel to the virtual plane V1 and including the wiring members 301₂ and the space S2 is defined. The virtual plane V2 is an example of a second virtual plane, and the virtual plane V3 is an example of a third virtual plane. FIG. 4B is a schematic section view of the module 100 taken along the virtual plane V2. FIG. 4C is a schematic section view of the module 100 taken along the virtual plane V3.

To be noted, although description has been given above on the premise that the module 100 includes the plurality of connecting units 300, this can be also referred to as a case where the module 100 includes one connecting unit 300 and the connecting unit 300 includes a plurality of wiring members 301₁ and a plurality of wiring members 301₂. In the description with reference to FIGS. 4A to 4C below, it is assumed that a connecting unit 300 includes two wiring members 301₁ and two wiring members 301₂. Among the two wiring members 301₁, one can serve as a first wiring member, and the other can serve as a third wiring member. In addition, among the two wiring members 301₂, one can serve as a second wiring member, and the other can serve as a fourth wiring member. In the virtual plane V2, the other of the two wiring members 301₁ is disposed apart from the one of the two wiring members 301₁. In the virtual plane V3, the other of the two wiring members 301₂ is disposed apart from the one of the two wiring members 301₂. The one of the two wiring members 301₁ is bonded to the one of the two wiring members 301₂ via the plurality of bonding members 350. The other of the two wiring members 301₁ is bonded to the other of the two wiring members 301₂ via the plurality of bonding members 350.

At least one of the following conditions (i) and (ii) is preferably satisfied.
(i) In the virtual plane V2, the space S1 is continuous with a space S3 that is on the opposite side of the wiring members 301₁ with respect to the space S1.
(ii) In the virtual plane V3, the space S2 is continuous with a space S4 that is on the opposite side of the wiring members 301₂ with respect to the space S2.

The space S3 is an example of a third space. The space S4 is an example of a fourth space. In the example of FIGS. 4A to 4C, both of the conditions (i) and (ii) are satisfied. The spaces S1 and S3 are continuous via the openings OP1 and OP2, and the spaces S2 and S4 are continuous via the openings OP1 and OP2.

As descried above, according to the configuration illustrated in FIGS. 4A to 4C, the spaces S1 and S3 are continuous via the openings OP1 and OP2, and the spaces S2 and S4 are continuous via the openings OP1 and OP2. Therefore, the flow of a fluid such as air is secured between the spaces S1 and S2 and the spaces S3 and S4, and thus the heat dissipation efficiency of the electronic component 102 is further improved.

To be noted, one of the wiring members 301₁ and the wiring members 301₂ in the connecting unit 300 may be configured to continuously surround the space S0. For example, one of the wiring members 301₁ and the wiring members 301₂ in the connecting unit 300 may be a wiring member having a frame shape.

Next, as illustrated in FIGS. 1 and 2, the dimension of the wiring member 301₁ in the lengthwise direction is larger than the dimension of the wiring member 301₁ in the width direction. The dimension of the wiring member 301₁ in the width direction is larger than the dimension of the wiring member 301₁ in the height direction. The dimension of the electronic component 102 in the height direction will be denoted by H0. The dimension of the wiring member 301₁ in the height direction will be denoted by H1. The dimension of the wiring member 301₂ in the height direction will be denoted by H2. The dimension H1 of the wiring member 301₁ in the height direction may be equal to (H1=H2) or different from the dimension H2 of the wiring member 301₂ in the height direction. The dimension H1 of the wiring member 301₁ in the height direction may be larger (H1>H2) or smaller (H1<H2) than the dimension H2 of the wiring member 301₂ in the height direction. At least one, preferably both of the dimension H1 of the wiring member 301₁ in the height direction and the dimension H2 of the wiring member 301₂ in the height direction may be smaller than the dimension H0 of the electronic component 102 (H1<H0 and/or H2<H0). According to such a configuration, the distance between the two wiring boards 101 and 201 can be adjusted more appropriately in accordance with the dimension H0 of the electronic component 102 in the height direction. In the case of focusing on increasing the interval between the electronic component 102 and the wiring board 101, at least one, preferably both of the dimension H1 of the wiring member 301₁ in the height direction and the dimension H2 of the wiring member 301₂ in the height direction may be larger than the dimension H0 of the electronic component 102 (H1>H0 and/or H2>H0). A configuration in which one of the dimensions H1 and H2 is smaller than the dimension H0 and the other of the dimensions H1 and H2 is larger than the dimension H0 may be also employed (H1>H0>H2 or H1<H0<H2).

The number of lines in the connecting unit 300 is determined in accordance with the components mounted on the wiring board 201. In the case where a large number of lines are needed, it is preferable that lines included in each of the wiring members 301₁ and 301₂, that is, the columnar portions 330₁ and 330₂ of the conductive members 320₁ and 320₂ are made to be as thin as possible so as to make the area of the main surface of each of the wiring boards 101 and 201 smaller.

In the first embodiment, the height of the wiring member 301₁ in the Z direction is smaller than the height of the electronic component 102 in the Z direction. That is, the dimension H1 of the wiring member 301₁ in the height direction is smaller than the dimension H0 of the electronic component 102 in the height direction. In addition, the height of the wiring member 301₂ in the Z direction is smaller than the height of the electronic component 102 in the Z direction. That is, the dimension H2 of the wiring member 301₂ in the height direction is smaller than the dimension H0 of the electronic component 102 in the height direction.

That is, by making the wiring members 301₁ and 301₂ thinner than the electronic component 102, the lines in the wiring members 301₁ and 301₂ can be made thinner, and thus the lines can be highly densely arranged in the wiring members 301₁ and 301₂. Therefore, the dimensions of the wiring members 301₁ and 301₂ in the lengthwise direction and the width direction can be reduced. Further, by laminating the wiring members thinner than the electronic component 102 into a plurality of layers, the distance between the two wiring boards 101 and 201 can be adjusted. As a result of this, for example, the number of layers of the wiring members can be adjusted in accordance with the height of the electronic component 102 in the Z direction, and therefore the module 100 can be miniaturized. In addition, the interval between the electronic component 102 and the wiring board 101 can be increased, and thus the heat dissipation efficiency of the electronic component 102 can be improved.

To be noted, although a case where the heat of the electronic component 102 is dissipated by natural convection has been described in the first embodiment, the configuration is not limited to this, and an unillustrated fan may be disposed. The heat of the electronic component 102 may be dissipated by forced convection caused by the fan.

### Example 1

Example 1 corresponding to the first embodiment will be described. In Example 1, the module 100 was manufactured by using the wiring members 301₁ and 301₂. The configuration of the wiring member 301₂ was the same as the configuration of the wiring member 301₁, and the dimensions of the wiring member 301₂ were also the same as the dimensions of the wiring member 301₁. The wiring member 301₁ will be described below.

First, the wiring member 301₁ was prepared. The dimension of the insulating substrate 310₁ of the wiring member 301₁ in the lengthwise direction was set to 20.00 mm. The dimension of the insulating substrate 310₁ in the width direction was set to 3.00 mm. The dimension of the insulating substrate 310₁ in the height direction was set to 0.60 mm. The diameter of the through hole 311₁ of the insulating substrate 310₁ was set to 0.15 mm. The diameter of the pads 331₁ and 332₁ was set to 0.325 mm. The pitch of the through holes 311₁, that is, the pitch of the conductive members 320₁ was set to 0.40 mm. The number of the through holes 311₁, that is, the number of the conductive members 320₁ was set to 272. As the wiring member 301₂, the same thing as the wiring member 301₁ was prepared.

To bond the wiring member 301₁ to the wiring member 301₂, solder balls of φ250 μm were used. The pads 331₁ of the wiring member 301₁ and the pads 331₂ of the wiring member 301₂ were bonded via solder by reflow. The interval between the pads 331₁ and 331₂ bonded to each other via the bonding members 350 that were solder was about 0.2 mm. That is, the interval between the wiring member 301₁ and the wiring member 301₂ was about 0.2 mm.

Next, solder paste was applied, by printing, on the pads 210 of the wiring board 201 on which the electronic components 221 and 222 were mounted, thus a laminate structure obtained by laminating the wiring member 301₂ on the wiring member 301₁ was mounted on the wiring board 201. The wiring board 201 on which the laminate structure was mounted was conveyed to a reflow furnace, and the pads 210 of the wiring board 201 and the pads 332₂ of the wiring member 301₂ were bonded to each other via solder by reflow.

Then, solder paste was applied, by printing, on the pads 110 of the wiring board 101 on which the electronic component 102 was mounted, thus a structure formed from the above-described laminate structure and the wiring board 201 was mounted on the wiring board 101. The wiring board 101 on which the structure was mounted was conveyed to a reflow furnace, and the pads 110 of the wiring board 101 and the pads 332₁ of the wiring member 301₁ were bonded to each other via solder by reflow. As a result of this, the module 100 of Example 1 was obtained.

The interval between the wiring boards 101 and 201 in the module 100 was about 1.5 mm. The height of the electronic component 102 was about 0.9 mm, and the interval between the electronic component 102 and the wiring board 201 was about 0.6 mm.

As described above, since the interval between the electronic component 102 and the wiring board 201, that is, the volume of the space A1 is set to be larger by an amount corresponding to the height of the wiring member 301₂, and therefore the heat dissipation efficiency of the electronic component 102 is improved.

### Modification Examples of First Embodiment

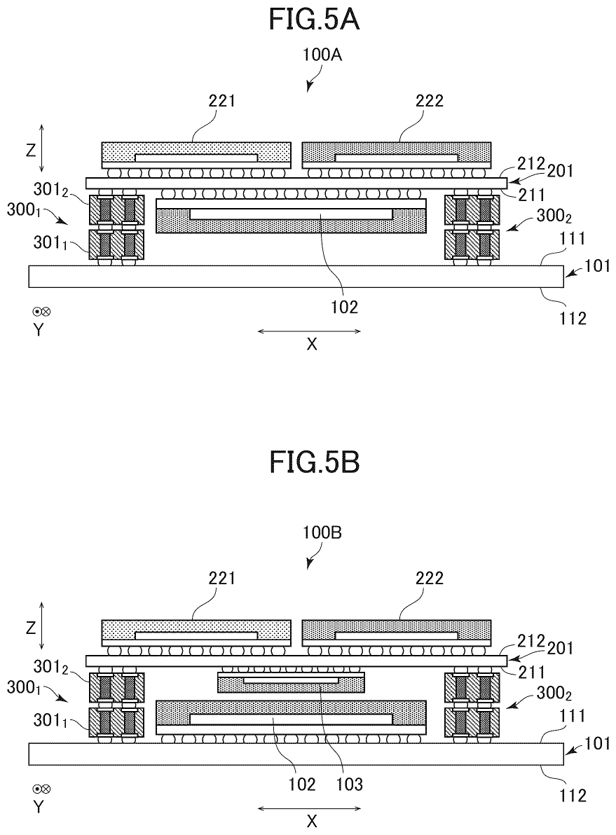

A first modification example, a second modification example, and a third modification example will be described as modification examples of the first embodiment. FIG. 5A is a section view of a module 100A of the first modification example. As illustrated in FIG. 5A, the electronic component 102 disposed between the wiring boards 101 and 201 may be mounted on the main surface 211 of the wiring board 201.

FIG. 5B is a section view of a module 100B of the second modification example. The at least one electronic component disposed between the wiring boards 101 and 201 may be a plurality of electronic components. For example, as illustrated in FIG. 5B, a plurality of electronic components, for example, two electronic components 102 and 103 may be disposed between the wiring boards 101 and 201. Further, the plurality of electronic components each may be mounted on the main surface 111 of the wiring board 101 or the main surface 211 of the wiring board 201. For example, the electronic component 102 may be mounted on the main surface 111, and the electronic component 103 may be mounted on the main surface 211.

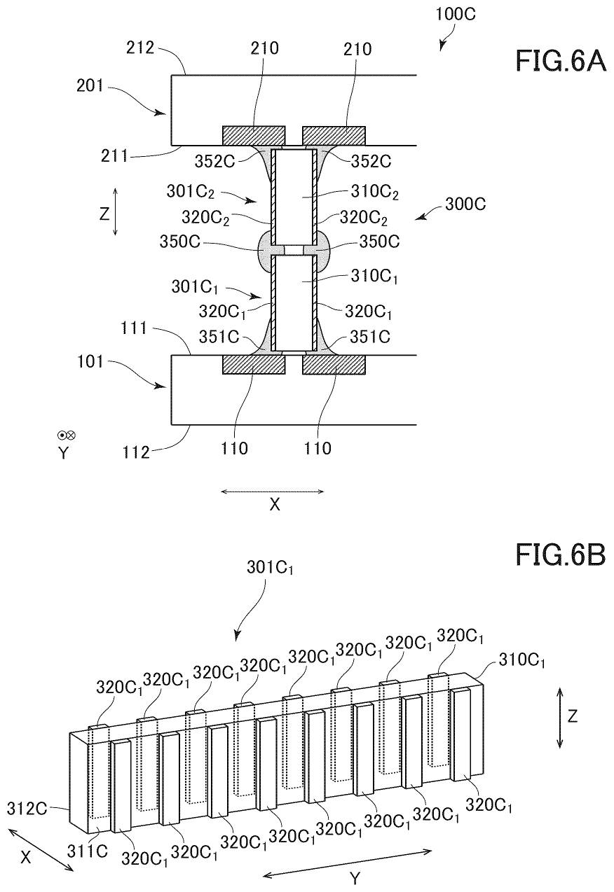

FIG. 6A is a section view of a module 100C of the third modification example. The module 100C includes wiring boards 101 and 201, and a plurality of, for example, two connecting units 300C disposed between the wiring boards 101 and 201. To be noted, FIG. 6A illustrates one of the two connecting units 300C.

The electronic component 102 illustrated in FIG. 1 is mounted on the wiring board 101, and electronic components 221 and 222 illustrated in FIG. 1 are mounted on the wiring board 201. The positional relationship of the two connecting units 300C with the electronic component 102 and the wiring boards 101 and 201 is the same as the positional relationship of the two connecting units 300 with the electronic component 102 and the wiring boards 101 and 201 described in the first embodiment.

The connecting unit 300C includes a plurality of wiring members arranged in the Z direction. The wiring members are each a wiring board. Each wiring member is preferably a rigid wiring board. In addition, each wiring member is preferably a two-layer printed wiring board that is easy to manufacture.

The plurality of wiring members are two wiring members 301C₁ and 301C₂ in the third modification example. The wiring member 301C₁ is an example of a first wiring member, and the wiring member 301C₂ is an example of a second wiring member. In the Z direction, at least part of the wiring member 301C₂ overlaps with the wiring member 301C₁.

In addition, the connecting unit 300C includes a plurality of bonding members 350C bonding the wiring member 301C₁ and the wiring member 301C₂ to each other, a plurality of bonding members 351C bonding the wiring member 301C₁ to the wiring board 101, and a plurality of bonding members 352C bonding the wiring member 301C₂ to the wiring board 201.

The bonding members 350C to 352C are members serving as part of the wiring electrically and mechanically interconnecting the wiring boards 101 and 201. The bonding members 350C to 352C are each, for example, a conductive member including solder. The solder is preferably solder of Sn—Ag—Cu or solder of Sn—Bi.

To be noted, although the bonding members 350C, 351C, and 352C preferably include solder, the configuration is not limited to this. For example, the bonding members 350C, 351C, and 352C may include an inorganic material such as copper, silver, gold, or aluminum, or may may include an organic material such as conductive rubber. In addition, the bonding members 350C, 351C, and 352C each may be, for example, a cured product of an organic conductive adhesive. In addition, the bonding members 350C, 351C, and 352C each may be an ACF.

The wiring member 301C₁ includes an insulating substrate 310C₁ and a plurality of conductive members 320C₁ provided on the insulating substrate 310C₁. The insulating substrate 310C₁ is a substrate having a rectangular parallelepiped shape. The insulating substrate 310C₁ is an example of a first insulating substrate. The insulating substrate 310C₁ is constituted by an insulating member. For example, the insulating substrate 310C₁ is preferably a member based on resin such as FR-4, but may be a member based on an inorganic material such as ceramics.

The conductive members 320C₁ are each an example of a first conductive member. The conductive members 320C₁ are each a metal member. The material of the metal member is not limited, but is preferably, for example, copper, silver, gold, aluminum, or the like. The manufacturing method of each conductive member 320C₁ is not limited, and possible examples thereof include a method of plating the insulating substrate 310C₁ with metal, a method of supplying a metal paste to the insulating substrate 310C₁ and curing the metal paste, and a method of compression-bonding a metal foil.

The wiring member 301C₂ includes an insulating substrate 310C₂ and a plurality of conductive members 320C₂ provided on the insulating substrate 310C₂. The insulating substrate 310C₂ is a substrate having a rectangular parallelepiped shape. The insulating substrate 310C₂ is an example of a second insulating substrate. The insulating substrate 310C₂ is constituted by an insulating member. For example, the insulating substrate 310C₂ is preferably a member based on resin such as FR-4, but may be a member based on an inorganic material such as ceramics.

The conductive members 320C₂ are each an example of a second conductive member. The conductive members 320C₂ are each a metal member. The material of the metal member is not limited, but is preferably, for example, copper, silver, gold, aluminum, or the like. The manufacturing method of each conductive member 320C₂ is not limited, and possible examples thereof include a method of plating the insulating substrate 310C₂ with metal, a method of supplying a metal paste to the insulating substrate 310C₂ and curing the metal paste, and a method of compression-bonding a metal foil.

In the third modification example, the configuration of the wiring member 301C₂ is substantially the same as the configuration of the wiring member 301C₁. The wiring member 301C₁ will be described in detail. FIG. 6B is a perspective view of the wiring member 301C₁ of the third modification example.

The insulating substrate 310C₁ has two side surfaces 311C and 312C formed at an interval in the X direction serving as a width direction. Among the plurality of conductive members 320C₁, two or more conductive members 320C₁ are provided on the side surface 311C of the insulating substrate 310C₁ at an interval from each other in the Y direction. Among the plurality of conductive members 320C₁, other two or more conductive members 320C₁ are provided on the side surface 312C of the insulating substrate 310C₁ at an interval from each other in the Y direction. In the third modification example, the conductive members 320C₁ are each provided to extend from a first end to a second end in the Z direction serving as the height direction of the insulating substrate 310C₁.

The connection relationship of each member in the connecting unit 300C will be described. Description will be given below focusing on one conductive member 320C₁, one conductive member 320C₂, one bonding member 350C, one bonding member 351C, one bonding member 352C, one pad 110, and one pad 210 corresponding to each other. As illustrated in FIG. 6A, the conductive member 320C₁ of the wiring member 301C₁ and the conductive member 320C₂ of the wiring member 301C₂ are bonded to each other via the bonding member 350C. The pad 110 of the wiring board 101 is bonded to the conductive member 320C₁ of the wiring member 301C₁ via the bonding member 351C. The pad 210 of the wiring board 201 is bonded to the conductive member 320C₂ of the wiring member 301C₂ via the bonding member 352C.

According to the connecting unit 300C of the configuration described above, the pad 210 of the wiring board 201 is electrically connected to the pad 110 of the wiring board 101 via the bonding member 352C, the conductive member 320C₂ of the wiring member 301C₂, the bonding member 350C, the conductive member 320C₁ of the wiring member 301C₁, and the bonding member 351C. As described above, the connecting unit 300C may be disposed between the wiring boards 101 and 201 instead of the connecting unit 300.

In addition, although the illustration thereof is omitted, the electronic component 102 may be mounted on the main surface 112 of the wiring board 101. There is a case where the heat generated in the electronic component 102 is conducted to the wiring board 101 and is dissipated to the space S0 between the wiring boards 101 and 201 from the wiring board 101. Since the interval between the two wiring boards 101 and 201 is increased by the connecting unit 300 or 300C, the influence of the heat dissipated to the space S0 can be reduced. Therefore, a module advantageous for improvement of the structure between the two wiring boards 101 and 201 can be provided.

In addition, although the illustration thereof is omitted, in the connecting unit 300, the wiring member 301₂ may be displaced in a direction parallel to the main surface 111 with respect to the wiring member 301₁. In this case, in a direction orthogonal to the main surface 111, part of the wiring member 301₂ may overlap with part of the wiring member 301₁. The wiring member 301₂ may have a part that overlaps with the wiring board 201 and a part that does not overlap with the wiring board 201 (part projecting from the wiring board 201 in plan view of the main surface 111) in the direction orthogonal to the main surface 111. The part of the wiring member 301₂ overlapping with the wiring board 201 may be bonded to the wiring board 201, and the part not overlapping with the wiring board 201 of the wiring member 301₂ may be bonded to the wiring member 301₁. In this case, the bonding member 350 bonding the wiring member 301₁ and the wiring member 301₂ to each other does not have to be disposed between the wiring boards 101 and 201 in the direction orthogonal to the main surface 111.

Similarly, although the illustration thereof is omitted, in the connecting unit 300C, the wiring member 301C₂ may be displaced in the direction parallel to the main surface 111 with respect to the wiring member 301C₁. In this case, in the direction orthogonal to the main surface 111, part of the wiring member 301C₂ may overlap with part of the wiring member 301C₁.

### Second Embodiment

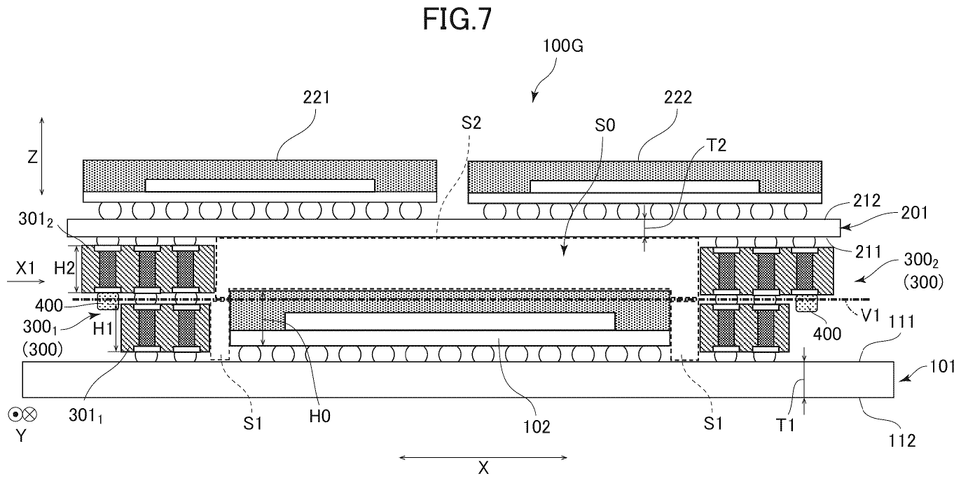

Next, a module of a second embodiment will be described. FIG. 7 is a section view of a module 100G according to the second embodiment. To be noted, in the configuration of the module 100G of the second embodiment, the same elements as in the module 100 of the first embodiment will be denoted by the same reference signs, and description thereof will be omitted.

The module 100G is an example of an electronic module, and has a three-dimensional mounting structure. The module 100G is different from the module 100 of the first embodiment in that electronic components 400 are mounted on the connecting unit 300. The thickness T2 of the wiring board 201 in the Z direction is smaller than the thickness T1 of the wiring board 101 in the Z direction. Therefore, the stiffness of the wiring board 201 is lower than the stiffness of the wiring board 101.

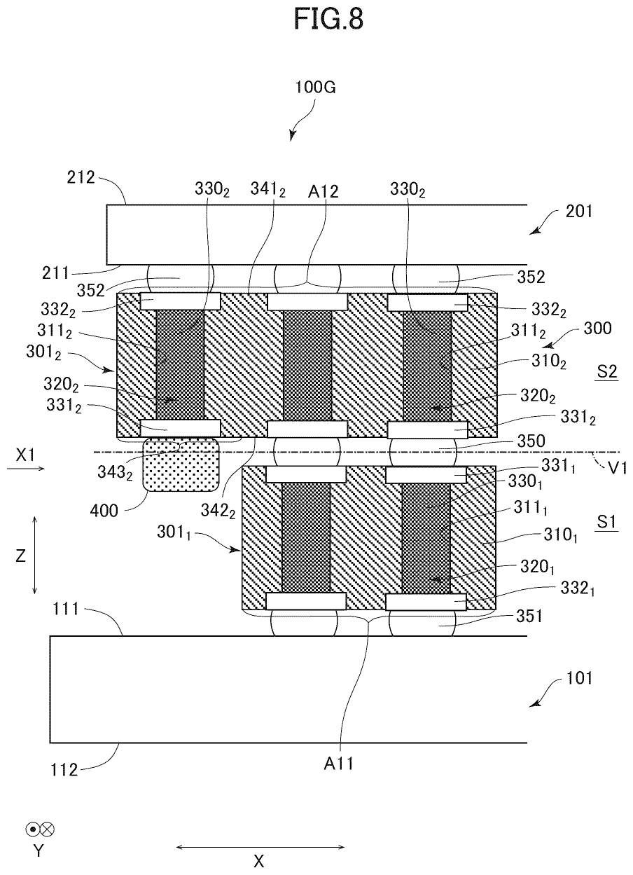

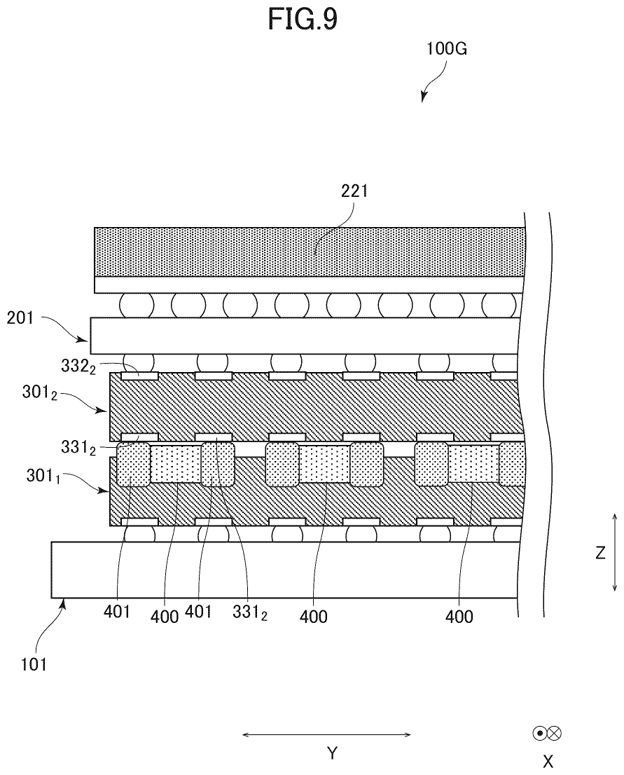

FIG. 8 is a section view of part of the module 100G according to the second embodiment. FIG. 9 is a side view of the module 100G according to the second embodiment. FIG. 9 schematically illustrates the module 100G as viewed in an X1 direction in FIGS. 7 and 8. The X1 direction is a direction parallel to the X direction.

In the second embodiment, the wiring member 301₂ is larger than the wiring member 301₁ in plan view, that is, as viewed in the Z direction. Further, in the Z direction, a part of the wiring member 301₂ overlaps with the wiring member 301₁, and another part of the wiring member 301₂ does not overlap with the wiring member 301₁. To be noted, the relationship between the dimension H0 of the electronic component 102 in the height direction, the dimension H1 of the wiring member 301₁ in the height direction, and the dimension H2 of the wiring member 301₂ in the height direction are as described in the first embodiment.

As described above, since the wiring board 201 is thinner than the wiring board 101, the stiffness of the wiring board 201 is lower than the stiffness of the wiring board 101. In the second embodiment, in the Z direction, the area A12 of a part surrounded by the outer shape of the wiring member 301₂ is larger than the area A11 of a part surrounded by the outer shape of the wiring member 301₁. Further, the number of the plurality of bonding members 352 is larger than the number of the plurality of bonding members 351. To be noted, the area A12 is equal to the area of a projection region obtained by projecting the wiring member 301₂ onto the virtual plane V1, and the area A11 is equal to the area of a projection region obtained by projecting the wiring member 301₁ onto the virtual plane V1.

Since heat generated in the electronic component 102 and the electronic components 221 and 222 can be conducted to the wiring board 201, the wiring board 201 having a lower stiffness than the wiring board 101 is more likely to be deformed by heat. Since the wiring board 201 having a lower stiffness than the wiring board 101 is bonded to the wiring member 301₂ having the area A12 larger than the area A11 via the plurality of bonding members 352, stress generated by thermal deformation of the wiring board 201 is distributed to the plurality of bonding members 352, and thus the reliability of the bonding between the wiring board 201 and the wiring member 301₂ is improved.

A surface 342₂ of the wiring member 301₂ on the wiring member 301₁ side includes a region 343₂ that does not overlap with the wiring member 301₁ in the Z direction. The surface 342₂, that is, the region 343₂ intersects with the Z direction (at a right angle in the present embodiment). A plurality of pads 331₂ not connected to the wiring member 301₁ via the bonding members 350 are disposed in the region 343₂. The module 100G includes electronic components 400 mounted on the region 343₂ of the surface 342₂. The electronic components 400 are each an example of a third electronic component. In the second embodiment, the electronic components 400 are each a capacitor serving as an example of a driven component. The electronic components 400 are each a chip component, and are surface-mounted on the region 343₂. The electronic components 400 are disposed on the side opposite to the side of the spaces S1 and S2 interposed between the plurality of connecting units 300. That is, the wiring member 301₂ projects more than the wiring member 301₁ to the side opposite to the side of the spaces S1 and S2, and the electronic components 400 are mounted on the part of the wiring member 301₂ projecting more than the wiring member 301₁.

Specifically, the number of the conductive members 320₂ of the wiring member 301₂ is larger than the number of the conductive members 320₁ of the wiring member 301₁. The electronic components 400 each include two electrodes 401. The two electrodes 401 are respectively bonded to two pads 331₂ of two conductive members 320₂ in the region 343₂ via bonding members such as solder. That is, the electronic components 400 are each electrically and mechanically connected to two conductive members 320₂ in the region 343₂.

One of the two conductive members 320₂ in the region 343₂ is part of the power supply line, and is electrically connected to power supply terminals of the electronic components 221 and 222 via the bonding members 352 and the wiring board 201. The other of the two conductive members 320₂ in the region 343₂ is part of the grounding line, and is electrically connected to the ground terminals of the electronic components 221 and 222 via the bonding members 352 and the wiring board 201. As a result of this, the electronic component 400 functions as a bypass capacitor for the electronic components 221 and 222. That is, the electronic component 400 is used for addressing the noises of the electronic components 221 and 222 or stabilizing the power supply.

As described above, according to the second embodiment, the wiring member 301₁ and the wiring member 301₂ are laminated between the wiring boards 101 and 201 so as to electrically interconnect the wiring boards 101 and 201. Therefore, the wiring members 301₁ and 301₂ can be respectively manufactured by using thin insulating substrates 310₁ and 310₂. Since through holes are bored in the insulating substrates 310₁ and 310₂ by using a drill of a small outer diameter, the diameter of the through holes can be set to be small to arrange the through holes at a small pitch. As a result, increase in the size of the wiring members 301₁ and 301₂ can be suppressed even when the number of lines in the wiring members 301₁ and 301₂ increases, and thus increase in the size of the module 100G can be suppressed.

In addition, since the area A12 of the wiring member 301₂ as viewed in the Z direction is larger than the area A11 of the wiring member 301₁ as viewed in the Z direction, the number of the bonding members 352 bonding the wiring board 201 to the wiring member 301₂ can be set to be larger than the number of the bonding members 351, that is, the number of the bonding members 350. As a result of this, the reliability of the bonding between the wiring board 201 that has a low stiffness and a large thermal deformation amount and the wiring member 301₂ can be improved.

In addition, the wiring member 301₂ can include wiring in the region 343₂ on the outside of the wiring member 301₁. Therefore, the electronic components 400 such as bypass capacitors can be mounted on the region 343₂, thus the noises of the electronic components 221 and 222 mounted on the wiring board 201 can be addressed, and power supply to the electronic components 221 and 222 can be stabilized.

### Example 2

Example 2 corresponding to the second embodiment will be described. In Example 2, the module 100G was manufactured by preparing the wiring members 301₁ and 301₂ and the electronic components 400. The configuration of the wiring members 301₁ and 301₂ and the electronic components 400 and the manufacturing method for the module 100G in Example 2 will be described below.

The dimension of the insulating substrate 310₂ of the wiring member 301₂ in the lengthwise direction was set to 20.00 mm. The dimension of the insulating substrate 310₂ in the width direction was set to 3.60 mm. The dimension of the insulating substrate 310₂ in the height direction was set to 0.60 mm. The diameter of the through holes 311₂ of the insulating substrate 310₂ was set to 0.15 mm. The diameter of the pads 331₂ and 332₂ was set to 0.325 mm. The pitch of the through holes 311₂ was set to 0.40 mm in a staggered layout. The total number of the through holes 311₂ per wiring member 301₂ was set to 306.

The length of a diagonal line connecting two through holes in the through holes 311₂ was set to 0.57 mm. Since the distance between the two pads 331₂ was also 0.57 mm, the electronic component 400 that is a capacitor was mounted on the two pads 331₂ by using a solder paste. The size of the electronic component 400 in plan view was a 0603 size that is a size of 0.6 mm×0.3 mm. To be noted, the description of the 0603 size conforms to the size description method (mm-based) of electronic components in Japanese Industrial Standards (JIS).

The dimension of the insulating substrate 310₁ of the wiring member 301₁ in the lengthwise direction was set to 20.00 mm. The dimension of the insulating substrate 310₁ in the width direction was set to 3.00 mm. The dimension of the insulating substrate 310₁ in the height direction was set to 0.60 mm. The diameter of the through holes 311₁ of the insulating substrate 310₁ was set to 0.15 mm. The diameter of the pads 331₁ and 332₁ was set to 0.325 mm. The pitch of the through holes 311₁ was set to 0.40 mm in a staggered layout. The total number of the through holes 311₁ per wiring member 301₁ was set to 272.

To bond the wiring member 301₁ to the wiring member 301₂, solder balls of φ250 μm were used. The pads 331₁ of the wiring member 301₁ and the pads 331₂ of the wiring member 301₂ were bonded to each other via solder by reflow. The solder balls served as the bonding members 350 after bonding. The distance between the pads 331₁ of the wiring member 301₁ and the pads 331₂ of the wiring member 301₂ after the bonding was about 0.2 mm.

Next, solder paste was applied, by printing, on the pads of the wiring board 201 on which the electronic components 221 and 222 were mounted, thus a laminate structure obtained by laminating the wiring member 301₂ on the wiring member 301₁ was mounted on the wiring board 201. The wiring board 201 on which the laminate structure was mounted was conveyed to a reflow furnace, and the pads of the wiring board 201 and the pads 332₂ of the wiring member 301₂ were bonded to each other via solder by reflow.

Then, solder paste was applied, by printing, on the pads of the wiring board 101 on which the electronic component 102 was mounted, thus a structure formed from the above-described laminate structure and the wiring board 201 was mounted on the wiring board 101. The wiring board 101 on which the structure was mounted was conveyed to a reflow furnace, and the pads of the wiring board 101 and the pads 332₁ of the wiring member 301₁ were bonded to each other via solder by reflow. As a result of this, the module 100G of Example 2 was obtained.

As a result of laminating the wiring members 301₁ and 301₂, the pitch of the through holes 311₁ and the pitch of the through holes 311₂ were set to 0.40 mm, which was a small pitch.

In contrast, in the case where the wiring member 301Y of Comparative Example 2 illustrated in FIG. 14B, the pitch of through holes is 0.60 mm. That is, the area of the connecting unit 300 including the wiring members 301₁ and 301₂ of Example 2 as viewed in the Z direction can be reduced to about 45% of the area of the connecting unit 300Y that is the wiring member 301Y as viewed in the Z direction, and thus increase in the size of the module 100G caused by increase in the number of lines can be suppressed.

In addition, a module in which only the pads 332₂ in the wiring member 301₂ were bonded to the wiring board 201 via solder and the module 100G of Example 2 were prepared, and a thermal fatigue test was repeatedly performed. In the module in which only the pads 332₂ in the wiring member 301₂ were bonded to the wiring board 201 via solder, breakage of the solder was recognized before the 100-th cycle, but in the module 100G of Example 2, the solder did not break even when the thermal fatigue test was repeated by 100 cycles or more. As described above, it was confirmed that the reliability of the bonding is improved in the case where the wiring member 301₂ includes the pads 332₂ and the pads 332₂ are bonded to the wiring board 201 via solder. Therefore, by applying the module 100G of Example 2 to an electronic device, high reliability can be secured for the electronic device.

Further, since capacitors serving as the electronic components 400 are mounted on the pads 331₂ of the wiring member 301₂, the electronic components 400 are disposed in the vicinity of the electronic components 221 and 222, and thus the noises of the electronic components 221 and 222 can be efficiently reduced.

To be noted, although a case where the electronic components 400 are mounted on the part of the wiring member 301₂ projecting to the side (outer side) opposite to the side of the spaces S1 and S2 (inner side) has been described in the second embodiment, the configuration is not limited to this. For example, the wiring member 301₂ may project inward with respect to the wiring member 301₁, and the electronic components 400 may be mounted on the projecting part. In addition, for example, the wiring member 301₁ may project inward or outward with respect to the wiring member 301₂, and the electronic components 400 may be mounted on the projecting part.

### Third Embodiment

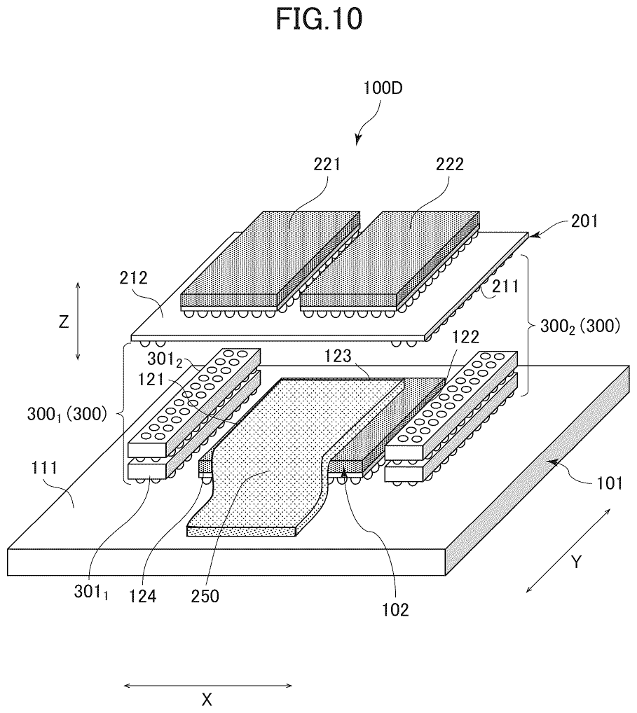

Next, a module of a third embodiment will be described. FIG. 10 is a section view of a module 100D according to the third embodiment. To be noted, in the configuration of the module 100D of the third embodiment, the same elements as in the module 100 of the first embodiment will be denoted by the same reference signs, and description thereof will be omitted.

The module 100D has a configuration in which a heat dissipation member 250 is further added to the module 100 of the first embodiment. The heat dissipation member 250 is provided on the electronic component 102. That is, since the interval between the electronic component 102 and the wiring board 201 is large, the heat dissipation member 250 can be disposed on the electronic component 102.

The heat dissipation member 250 includes, for example, a heat dissipation sheet such as a metal sheet, or a heat dissipation grease. Heat generated in the electronic component 102 is conducted to the heat dissipation member 250. The heat dissipation member 250 preferably extends to the outside from the open space between the wiring boards 101 and 201, that is, from the spaces S1 and S2 of FIG. 2. As described above, according to the third embodiment, since the heat dissipation member 250 is provided on the electronic component 102, the heat dissipation efficiency of the electronic component 102 is further improved.

To be noted, although heat is dissipated from the heat dissipation member 250, that is, from the electronic component 102 by natural convection has been described in the third embodiment, the configuration is not limited to this, and an unillustrated fan may be provided. The heat of the heat dissipation member 250, that is, the heat of the electronic component 102 may be dissipated by forced convection caused by the fan. In addition, the module 100D may be modified as in the plurality of modification examples of the first embodiment described above.

### Fourth Embodiment

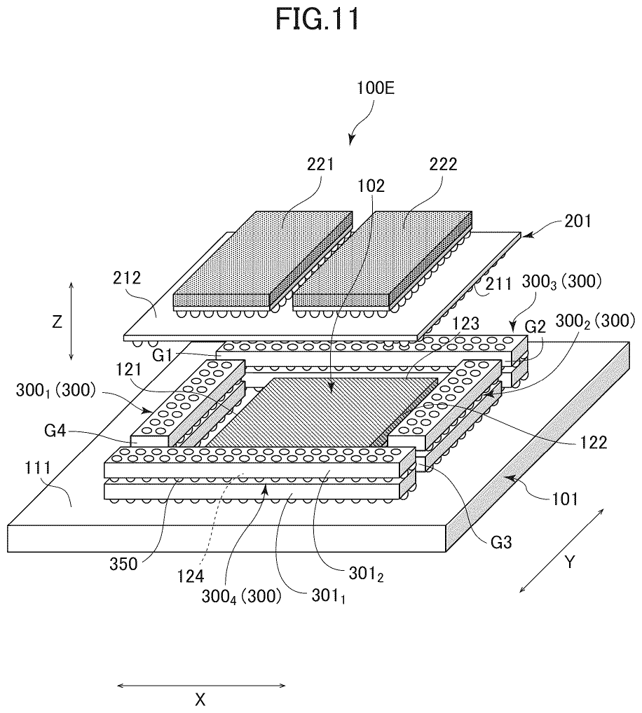

Next, a module of a fourth embodiment will be described. FIG. 11 is a section view of a module 100E according to the fourth embodiment. To be noted, in the configuration of the module 100E of the fourth embodiment, the same elements as in the module 100 of the first embodiment will be denoted by the same reference signs, and description thereof will be omitted.

The module 100E has a configuration in which connecting units 300₃ and 300₄ are further added to the module 100 of the first embodiment. That is, the module 100E includes four connecting units 300₁, 300₂, 300₃, and 300₄ as the plurality of connecting units 300. The configuration of the connecting units 300₃ and 300₄ is substantially the same as the configuration of the connecting units 300 described in the first embodiment, that is, the configuration of the connecting units 300₁ and 300₂.

The connecting unit 300₃ is an example of a third connecting unit. The connecting unit 300₄ is an example of a fourth connecting unit. The connecting unit 300₃ is disposed to face the side surface 123 of the electronic component 102 in the Y direction. The connecting unit 300₄ is disposed to face the side surface 124 of the electronic component 102 in the Y direction. In the fourth embodiment, at least part of the connecting unit 300₃ faces the side surface 123 of the electronic component 102 in the Y direction. In addition, at least part of the connecting unit 300₄ faces the side surface 124 of the electronic component 102 in the Y direction.

At least one of the wiring members 301₁ and the wiring members 301₂, both in the fourth embodiment, do not continuously surround the space S0 (spaces S1 and S2). In the example of FIG. 11, the plurality of wiring members 301₁ and the plurality of wiring members 301₂ both discontinuously surround the space S0 (spaces S1 and S2). That is, the space S0 is discontinuously surrounded by the plurality of wiring members 301₁ apart from each other and the plurality of wiring members 301₂ apart from each other. Further, the electronic component 102 is surrounded by the wiring boards 101 and 201 in the Z direction that is an up-down direction, and is discontinuously surrounded by the plurality of connecting units 300₁ to 300₄ arranged at intervals in the X direction and Y direction serving as four directions. The plurality of bonding members 350 are arranged at intervals between the wiring member 301₁ and the wiring member 301₂ of each of the connecting units 300₁ to 300₄.

In the fourth embodiment, there is a gap G1 between the connecting units 300₁ and 300₃, there is a gap G2 between the connecting units 300₃ and 300₂, there is a gap G3 between the connecting units 300₂ and 300₄, and there is a gap G4 between the connecting units 300₁ and 300₄. Further, the space S0 communicates with the outside space via the gaps G1 to G4. Here, the outside space is a space on the opposite side to the side of the space S0 with respect to the connecting units 300.

In addition to the gaps between the plurality of bonding members 350, the gaps G1 to G4 secure the flow of a fluid such as air between the space discontinuously surrounded by the plurality of connecting units 300₁ to 300₄ (that is, the spaces S1 and S2 of FIG. 2) and the outside space, and thus the heat dissipation efficiency of the electronic component 102 is improved. As described above, the heat dissipation property of the electronic component 102 is secured even in the case where the number of lines between the wiring boards 101 and 201 is large.

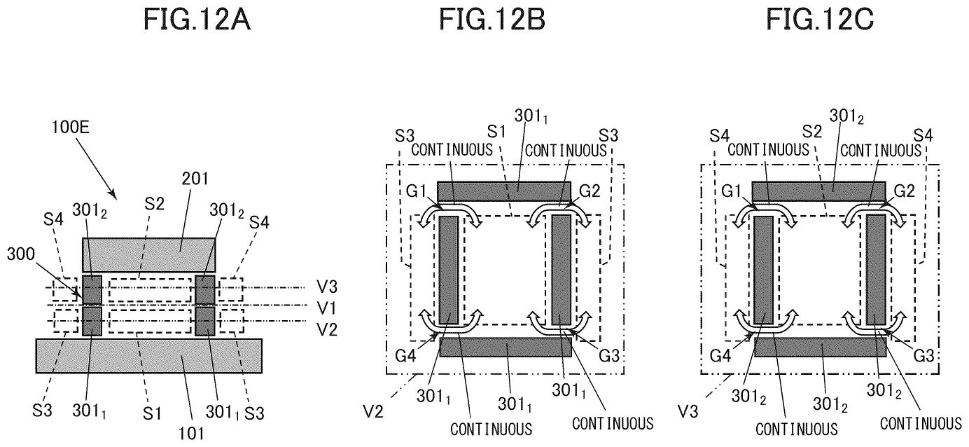

FIGS. 12A to 12C are explanatory diagrams of the module 100E of the fourth embodiment. FIG. 12A is a schematic section view of the module 100E in the X-Z plane. As illustrated in FIG. 12A, a virtual plane V2 parallel to the virtual plane V1 and including the wiring members 301₁ and the space S1 is defined. In addition, a virtual plane V3 parallel to the virtual plane V1 and including the wiring members 301₂ and the space S2 is defined. The virtual plane V2 is an example of a second virtual plane, and the virtual plane V3 is an example of a third virtual plane. FIG. 12B is a schematic section view of the module 100E taken along the virtual plane V2. FIG. 12C is a schematic section view of the module 100E taken along the virtual plane V3.

To be noted, although description has been given above on the premise that the module 100E includes the plurality of connecting units 300, this can be also referred to as a case where the module 100E includes one connecting unit 300 and the connecting unit 300 includes a plurality of wiring members 301₁ and a plurality of wiring members 301₂. In the description with reference to FIGS. 12A to 12C below, it is assumed that a connecting unit 300 includes four wiring members 301₁ and four wiring members 301₂. Two wiring members 301₁ adjacent to each other among the four wiring members 301₁ and two wiring members 301₂ adjacent to each other among the four wiring members 301₂ will be described. Among the two wiring members 301₁ adjacent to each other, one can serve as a first wiring member, and the other can serve as a third wiring member. In addition, among the two wiring members 301₂ adjacent to each other, one can serve as a second wiring member, and the other can serve as a fourth wiring member. In the virtual plane V2, the other of the two wiring members 301₁ is disposed apart from the one of the two wiring members 301₁. In the virtual plane V3, the other of the two wiring members 301₂ is disposed apart from the one of the two wiring members 301₂. The one of the two wiring members 301₁ is bonded to the one of the two wiring members 301₂ via the plurality of bonding members 350. The other of the two wiring members 301₁ is bonded to the other of the two wiring members 301₂ via the plurality of bonding members 350.

At least one of the following conditions (i) and (ii) is preferably satisfied.
(i) In the virtual plane V2, the space S1 is continuous with a space S3 that is on the opposite side of the wiring members 301₁ with respect to the space S1.
(ii) In the virtual plane V3, the space S2 is continuous with a space S4 that is on the opposite side of the wiring members 301₂ with respect to the space S2.

In the example of FIGS. 12A to 12C, both the conditions (i) and (ii) are satisfied. The spaces S1 and S3 are continuous via the gaps G1 and G4 or the gaps G2 and G3, and the spaces S2 and S4 are continuous via the gaps G1 and G4 or the gaps G2 and G3.

The plurality of wiring members 301₁ having rectangular shapes are arranged apart from each other in a frame shape. In addition, the plurality of wiring members 301₂ having rectangular shapes are arranged apart from each other in a frame shape. Since the plurality of wiring members 301₁ corresponding to sides of the frame shape are apart from each other and the plurality of wiring members 301₂ corresponding to sides of the frame shape are apart from each other, the gaps G1 to G4, that is, a flow path for the fluid such as air is formed.

According to the configuration illustrated in FIGS. 12A to 12C, as a result of the spaces S1 and S2 and the spaces S3 and S4 communicate with each other via the gaps G1 to G4, flow of the fluid such as air between the spaces S1 and S2 and the spaces S3 and S4 is secured, and thus the heat dissipation efficiency of the electronic component 102 is further improved.

To be noted, the wiring members 301₁ or the wiring members 301₂ in the connecting units 300 may be configured to continuously surround the space S0. For example, the wiring members 301₁ or the wiring members 301₂ in the connecting units 300 may be a wiring member of a frame shape.

To be noted, in the module 100E, the connecting unit 300₄ may be omitted. In addition, although a case where the heat of the electronic component 102 is dissipated by natural convection has been described in the fourth embodiment, the configuration is not limited to this, and an unillustrated fan may be disposed on the outside of the module 100E. The heat of the electronic component 102 may be dissipated by forced convection caused by the fan. In addition, the module 100E can be modified as in any of the plurality of modification examples of the first embodiment described above. In addition, in the module 100E of the fourth embodiment or a module of a modification example thereof, a heat dissipation member may be disposed on the electronic component 102 as in the third embodiment.

### Fifth Embodiment

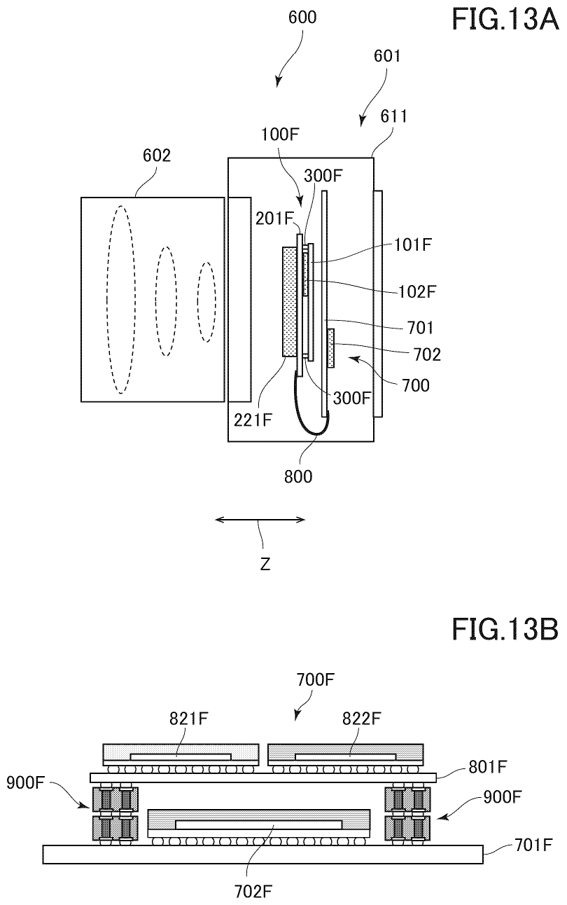

In the fifth embodiment, a case where one of the first to fourth embodiments or a modification example thereof is applied to an electronic device will be described. FIG. 13A is an explanatory diagram of a camera 600 according to the fifth embodiment. The camera 600 is a digital camera, and includes a camera body 601 and a replacing lens 602 detachably attached to the camera body 601. In the fifth embodiment, the camera body 601 is an example of an image pickup apparatus, and is an example of an electronic device.

The camera body 601 includes a casing 611, and an image pickup module 100F and an image processing module 700 that are disposed inside the casing 611. The image pickup module 100F and the image processing module 700 are electrically connected to each other via a flexible printed wiring board 800 such that data can be communicated therebetween. A signal indicating image data generated in the image pickup module 100F is transmitted to the image processing module 700 via the flexible printed wiring board 800. The signal indicating image data is a digital signal.

The image pickup module 100F is an example of a module, and has a three-dimensional mounting structure. The image pickup module 100F includes an image sensor 221F, a memory device 102F, wiring boards 101F and 201F, and a plurality of connecting units 300F. The image sensor 221F is mounted on the wiring board 201F, and the memory device 102F is mounted on the wiring board 101F. The image sensor 221F is, for example, a complementary metal oxide semiconductor (CMOS) image sensor, or a charge coupled device (CCD) image sensor.

The wiring board 101F is an example of a first wiring board, and the memory device 102F is an example of a first electronic component. The wiring board 201F is an example of a second wiring board, and the image sensor 221F is an example of a second electronic component. The connecting unit 300F has a configuration substantially the same as the connecting unit of any of the first to fourth embodiments or modification examples thereof.

The image processing module 700 includes a wiring board 701, and an image processing device 702 mounted on the wiring board 701. The image processing device 702 is, for example, a digital signal processor, and processes image data obtained from the image pickup module 100F.

As described above, according to the fifth embodiment, since the connecting units 300F of the image pickup module 100F have substantially the same configuration as the connecting units of a module of any of the first to fourth embodiments or a modification example thereof, the heat dissipation efficiency in the image pickup module 100F is improved, and also the image pickup module 100F can be miniaturized. Therefore, the camera body 601 can be miniaturized. To be noted, also the image processing module 700 may have a three-dimensional mounting structure similar to the first to fourth embodiments or a modification example thereof.

A fourth modification example that is a modification example of the image processing module 700 in the fifth embodiment will be described below. FIG. 13B is an explanatory diagram of the image processing module 700F serving as an example of a module of the fourth modification example. The image processing module 700F is an example of a module, and has a three-dimensional mounting structure. The image processing module 700F includes an image processing device 702F serving as an example of a first electronic component, memory devices 821F and 822F serving as examples of second electronic components, a wiring board 701F serving as an example of a first wiring board, a wiring board 801F serving as an example of a second wiring board, and a plurality of connecting units 900F. The connecting units 900F have substantially the same configuration as the connecting units of any of the first to fourth embodiments or modification examples thereof. In the example of FIG. 13B, the connecting units 900F are the connecting units 300. The image processing device 702F is, for example, a digital signal processor, and is capable of processing image data obtained from the image pickup module 100F illustrated in FIG. 13A and storing, in the memory devices 821F and 822F, the image data that has been or not has been processed. As described above, the connecting units of the first to fourth embodiments or the modification examples thereof can be applied to the image processing module 700F.

The present disclosure is not limited to the embodiments described above, and the embodiments can be modified in many ways within the technical concept of the present disclosure. In addition, the effects described in the embodiments are merely enumeration of the most preferable effects that can be obtained from the embodiments of the present disclosure, and the effects of the embodiments of the present disclosure are not limited to those described in the embodiments.

Although a case where the plurality of wiring members included in a connecting unit are two wiring members has been described as an example, the configuration is not limited to this. That is, the connecting unit may include three or more wiring members.

Although a case where the module described above is applied to an electronic device such as an image pickup apparatus has been described, the configuration is not limited to this. The module described above is also applicable to, for example, mobile devices and wearable devices such as smartphones, tablet computers, laptop computers, and portable gaming devices. In addition, the module described above is also appliable to electronic devices, for example, image processing apparatuses such as printers, copiers, facsimile machines, and multi-functional apparatuses having functions of these. In addition, the module described above is also applicable to communication devices such as modems and routers, medical devices such as X-ray imaging devices and endoscopes, industrial devices such as robots and semiconductor manufacturing apparatuses, and transportation devices such as cars, airplanes, and ships.

Further, the disclosure of the present specification is not limited to what is explicitly described in the present specification, and includes all matters that can be grasped from the present specification and drawings attached to the present specification. In addition, the disclosure of the present specification includes a complementary set of each individual concept described in the present specification. That is, for example, if the present specification includes a description of “A is B”, it can be said that the present disclosure also discloses a case of “A is not B” even if description of “A is not B” is omitted. This is because a case of “A is B” is described on the premise that a case of “A is not B” is considered.

As described above, according to the present disclosure, a module advantageous for improving the structure between two wiring boards can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-034354, filed Mar. 7, 2023, and Japanese Patent Application No. 2024-011234 filed Jan. 29, 2024, which are hereby incorporated by reference herein in their entirety.

What is claimed is:

1. A module comprising:
a first wiring board having a main surface;
a second wiring board disposed at an interval from the first wiring board and configured to overlap with the first wiring board in a direction orthogonal to the main surface;
an electronic component mounted on the first wiring board or the second wiring board; and
a connecting unit configured to interconnect the first wiring board and the second wiring board,
wherein the connecting unit includes
a first wiring member disposed on the first wiring board side with respect to a first virtual plane between the first wiring board and the second wiring board,
a second wiring member disposed on the second wiring board side with respect to the first virtual plane, and
a conductive bonding member configured to bond the first wiring member and the second wiring member to each other,
wherein between the first wiring board and the second wiring board, a first space continuous from the first wiring board to the first virtual plane and a second space continuous from the second wiring board to the first virtual plane are continuous with each other at the first virtual plane, and
wherein at least one of a first condition and a second condition is satisfied, the first condition being a condition that a third space on an opposite side to the first space with respect to the first wiring member is continuous with the first space in a second virtual plane parallel to the first virtual plane and including the first wiring member and the first space, the second condition being a condition that a fourth space on an opposite side to the second space with respect to the second wiring member is continuous with the second space in a third virtual plane parallel to the first virtual plane and including the second wiring member and the second space.

2. A module comprising:
a first wiring board having a main surface;
a second wiring board disposed at an interval from the first wiring board and configured to overlap with the first wiring board in a direction orthogonal to the main surface;
an electronic component disposed between the first wiring board and the second wiring board; and
a connecting unit configured to interconnect the first wiring board and the second wiring board,
wherein the connecting unit includes
a first wiring member configured to overlap with the first wiring board in the direction orthogonal to the main surface and not overlap with the electronic component in the direction orthogonal to the main surface,
a second wiring member configured to overlap with the second wiring board and the first wiring member in the direction orthogonal to the main surface and not overlap with the electronic component in the direction orthogonal to the main surface, and
a conductive bonding member configured to bond the first wiring member and the second wiring member to each other,
wherein at least one of the first wiring member and the second wiring member does not continuously surround a space between the first wiring board and the second wiring board.

3. A module comprising:
a first wiring board having a main surface;
a second wiring board disposed at an interval from the first wiring board and configured to overlap with the first wiring board in a direction orthogonal to the main surface;
an electronic component disposed between the first wiring board and the second wiring board; and
a connecting unit configured to interconnect the first wiring board and the second wiring board,
wherein the connecting unit includes
a first wiring member configured to overlap with the first wiring board in the direction orthogonal to the main surface and not overlap with the electronic component in the direction orthogonal to the main surface,
a second wiring member configured to overlap with the second wiring board and the first wiring member in the direction orthogonal to the main surface and not overlap with the electronic component in the direction orthogonal to the main surface, and
a conductive bonding member configured to bond the first wiring member and the second wiring member to each other,
wherein one of the first wiring member and the second wiring member has a region that does not overlap with another of the first wiring member and the second wiring member in the direction orthogonal to the main surface of the first wiring board, the region intersects with the direction, and a driven component is mounted on the region.

4. The module according to claim 1, wherein the electronic component is disposed between the first wiring board and the second wiring board.

5. The module according to claim 1,
wherein the first wiring member includes
a first insulating substrate, and
a first conductive member provided on the first insulating substrate.

6. The module according to claim 5,
wherein the first insulating substrate has a first through hole, and
wherein at least part of the first conductive member is provided in the first through hole.

7. The module according to claim 1,
wherein the second wiring member includes
a second insulating substrate, and
a second conductive member provided on the second insulating substrate.

8. The module according to claim 7,
wherein the second insulating substrate has a second through hole, and
wherein at least part of the second conductive member is provided in the second through hole.

9. The module according to claim 1, wherein the bonding member is solder.

10. The module according to claim 1, wherein the electronic component is mounted on the main surface of the first wiring board.

11. The module according to claim 2, wherein a height of the first wiring member in the direction orthogonal to the main surface is smaller than a height of the electronic component in the direction orthogonal to the main surface.

12. The module according to claim 2, wherein a height of the second wiring member in the direction orthogonal to the main surface is smaller than a height of the electronic component in the direction orthogonal to the main surface.

13. The module according to claim 1,
wherein the main surface is a first main surface,
wherein the electronic component is a first electronic component,
wherein the second wiring board has a second main surface facing the first main surface, and a third main surface provided on an opposite side to the second main surface, and
wherein the module further comprises a second electronic component mounted on the third main surface of the second wiring board.

14. The module according to claim 1,
wherein a stiffness of the second wiring board is lower than a stiffness of the first wiring board, and
in the direction orthogonal to the main surface, an area of a portion surrounded by an outer shape of the second wiring member is larger than an area of a portion surrounded by an outer shape of the first wiring member.

15. The module according to claim 1, wherein the number of bonding members bonding the second wiring board and the second wiring member to each other is larger than the number of bonding members bonding the first wiring board and the first wiring member to each other.

16. The module according to claim 1, wherein the second wiring board is thinner than the first wiring board.

17. The module according to claim 3, wherein the driven component is a capacitor.

18. The module according to claim 1, further comprising a heat dissipation member provided on the electronic component.

19. The module according to claim 1, wherein the module comprises a plurality of connecting units each serving as the connecting unit.

20. The module according to claim 19,
wherein the electronic component has a first side surface and a second side surface on an opposite side to the first side surface, and
wherein the plurality of connecting units include a first connecting unit disposed to face the first side surface and a second connecting unit disposed to face the second side surface.

21. The module according to claim 20,
wherein the electronic component has a third side surface and a fourth side surface on an opposite side to the third side surface, and
wherein the plurality of connecting units include a third connecting unit disposed to face the third side surface.

22. The module according to claim 1, wherein the connecting unit is disposed such that the first virtual plane is positioned between the first wiring member and the second wiring member and the bonding member is positioned in the first virtual plane.

23. The module according to claim 1,
wherein the connecting unit includes
a third wiring member disposed apart from the first wiring member in the second virtual plane,
a fourth wiring member disposed apart from the second wiring member in the third virtual plane, and
a conductive bonding member configured to bond the third wiring member and the fourth wiring member to each other.

24. The module according to claim 2, wherein the electronic component is an integrated circuit component.

25. An electronic device comprising:
the module according to claim 1; and
a casing in which the module is disposed.

26. The electronic device according to claim 25, wherein the electronic component of the module is an image processing device.

27. An electronic device comprising:
the module according to claim 13; and
a casing in which the module is disposed,
wherein the second electronic component of the module is an image sensor.
